(19) United States
(12) Patent Application Publication
(10) Pub. No.: US 2026/0173664 A1
(43) Pub. Date: Jun. 18, 2026

(54) DISPLAY PANEL AND DISPLAY DEVICE

(71) Applicants: Hefei Visionox Technology Co., Ltd., Hefei (CN); Hefei Visionox Electronics Co., Ltd., Hefei (CN); Visionox Technology Inc., Suzhou (CN)

(72) Inventors: Zhiwei ZHOU, Hefei (CN); Jinfang ZHANG, Hefei (CN); Yulong MA, Hefei (CN); Qingfeng XU, Hefei (CN); Tian WANG, Hefei (CN); Chung-Chun LEE, Hefei (CN)

(73) Assignees: Hefei Visionox Technology Co., Ltd., Hefei (CN); Hefei Visionox Electronics Co., Ltd., Hefei (CN); Visionox Technology Inc., Suzhou (CN)

(21) Appl. No.: 19/430,984

(22) Filed: Dec. 23, 2025

Related U.S. Application Data
(63) Continuation of application No. PCT/CN2025/132212, filed on Nov. 3, 2025.

(30) Foreign Application Priority Data
Dec. 13, 2024 (CN) 202411847052.2

(51) Int. Cl. H10K 59/122; H10K 59/35

(52) U.S. Cl. CPC H10K 59/122; H10K 59/353

(57) ABSTRACT

A display panel and a display device. The display panel includes a substrate, an isolation layer, and a light-emitting layer. The light-emitting units include first light-emitting units, second light-emitting units and third light-emitting units adjacent to the first light-emitting units in the second direction, and fourth light-emitting units adjacent to the first light-emitting units in the first direction. A width of the isolation structure located between the first light-emitting unit and the second light-emitting unit is a first sub-width, a width of the isolation structure located between the first light-emitting unit and the third light-emitting unit is a second sub-width, a width of the isolation structure located between the first light-emitting unit and the fourth light-emitting unit is a third sub-width. The width of the isolation structure between the adjacent first light-emitting unit and fourth light-emitting unit in the first direction is larger.

### CROSS REFERENCE TO RELATED APPLICATION

The present application is a continuation of International Application No, PCT/CN2025/132212, filed on Nov. 3, 2025, which claims priority to Chinese Patent Application No. 202411847052.2, filed on Dec. 13, 2024. All of the aforementioned patent applications are hereby incorporated by reference in their entireties.

### TECHNICAL FIELD

The present application relates to the technical field of display, and particularly to a display panel and a display device.

### BACKGROUND

Flat-panel display devices based on technologies such as Organic Light Emitting Diode (OLED) and Light Emitting Diode (LED) are widely used in various consumer electronic products such as mobile phones, televisions, laptop computers, and desktop computers due to their advantages of high image quality, low power consumption, thin profile, and wide application range, and have become mainstream in display devices.

In a traditional manufacturing process of the display panel, the graphics of light-emitting pixels are usually realized through a Fine Metal Mask (FMM). The FMM technology is mature and has rich mass production experience. However, the FMM technology also has issues such as limited precision, high development costs, and long development cycles. The non-FMM technology eliminates the limitations of traditional OLED processes on display size, resolution, and other screen performance, and provides advantages of high performance, full-area size, and agile delivery. Patents CN118251982A, CN115666161A, CN116648095A, CN117062489A, CN118678742A, CN118785761A, CN115224220A, CN118678729A, CN118660529A, and CN118660589A disclose the related content of the non-FMM technology for reference.

However, the performance of current OLED display products needs improvement.

### SUMMARY

The embodiments of the present application provide a display panel and a display device.

The embodiments of the present application provide a display panel comprising: a substrate; an isolation layer located on a side of the substrate, the isolation layer including an isolation structure and a plurality of isolation openings enclosed by the isolation structure; a light-emitting layer located on a side of the substrate, the light-emitting layer including a plurality of light-emitting units, at least a portion of the light-emitting unit being located in the isolation opening, the plurality of the light-emitting units being arranged along a first direction and a second direction that intersect, wherein, the plurality of light-emitting units include a plurality of first light-emitting units, a plurality of second light-emitting units, a plurality of third light-emitting units and a plurality of fourth light-emitting units, the second light-emitting unit and the third light-emitting unit are adjacent to the first light-emitting unit in the second direction, the fourth light-emitting unit is adjacent to the first light-emitting unit in the first direction, a width of the isolation structure located between the first light-emitting unit and the second light-emitting unit is a first sub-width, a width of the isolation structure located between the first light-emitting unit and the third light-emitting unit is a second sub-width, a width of the isolation structure located between the first light-emitting unit and the fourth light-emitting unit is a third sub-width, a sum of the first sub-width and the second sub-width is less than the third sub-width, and the first direction and the second direction intersect.

The embodiments of the present application further provide a display panel comprising: a substrate; an isolation layer located on a side of the substrate, the isolation layer including an isolation structure and a plurality of isolation openings enclosed by the isolation structure; a pixel definition layer located on a side of the substrate, wherein the pixel definition layer includes a pixel limiting portion and a plurality of pixel openings enclosed by the pixel limiting portion, and at least a part of the pixel openings correspond to and communicate with the isolation openings in a one-to-one correspondence; a light-emitting layer located on a side of the substrate, the light-emitting layer including a plurality of light-emitting units, at least a portion of the light-emitting unit being located within the pixel opening, wherein a first region and a second region are provided between adjacent light-emitting units, a width of the isolation structure in the first region is greater than a width of the isolation structure in the second region, and a width of the pixel limiting portion in the first region is greater than a width of the pixel limiting portion in the second region.

The embodiments of the present application provide a display device including the display panel of any of the above embodiments.

### BRIEF DESCRIPTION OF THE DRAWINGS

Other features, objectives, and advantages of the present application will become more apparent upon reading the following detailed description of non-limiting embodiments with reference to the accompanying drawings, here, the same or similar reference numerals represent the same or similar features, and the drawings are not necessarily drawn to scale.

FIG. 1 is a partial top view schematic diagram of a display panel provided by an embodiment of the present application;

FIG. 2 is a partial cross-sectional view of a display panel provided by an embodiment of the present application;

FIG. 3 is a partial top view schematic diagram of a display panel in another embodiment;

FIG. 4 is a partial top view schematic diagram of a display panel in yet another embodiment;

FIG. 5 is a partial top view schematic diagram of a display panel in a further embodiment;

FIG. 6 is a partial top view schematic diagram of a display panel in another embodiment;

FIG. 7 is a partial top view schematic diagram of a display panel in another embodiment;

FIG. 8 is a partial top view schematic diagram of a display panel in another embodiment;

FIG. 9 is a partial top view schematic diagram of a display panel in another embodiment;

FIG. 10 is a partial top view schematic diagram of a display panel in another embodiment;

FIG. 11 is a partial top view schematic diagram of a display panel in another embodiment;

FIG. 12 is a partial top view schematic diagram of a display panel in another embodiment;

FIG. 13 is a partial top view schematic diagram of a display panel in another embodiment;

FIG. 14 is a partial cross-sectional view of a display panel in another embodiment;

FIG. 15 is a partial cross-sectional view of a display panel in yet another embodiment;

FIG. 16 is a partial top view schematic diagram of a display panel in another embodiment;

FIG. 17 is a partial top view schematic diagram of a display panel in another embodiment;

FIG. 18 is a partial cross-sectional view of a display panel in a further embodiment;

FIG. 19 is a partial cross-sectional view of a display panel in another embodiment;

FIG. 20 is a partial cross-sectional view of a display panel in another embodiment.

### REFERENCE MARK DESCRIPTION

10: display panel; 11: first region; 12: second region; 13: overlapping region; 14: first reference plane; 15: second reference plane;
100: substrate; 110: drive circuit; 120: first insulating layer; 130: via;
200: isolation layer; 201: isolation structure; 202: first top surface; 203: second top surface; 210: first layer; 220: second layer; 230: third layer; 240: isolation opening; 240a: first side; 240b: second side; 240c: third side; 240d: fourth side; 240e: arc edge; 241: first isolation opening; 242: second isolation opening; 243: third isolation opening; 250: virtual quadrilateral;
300: light-emitting layer; 310: light-emitting unit; 311: first light-emitting unit; 312: second light-emitting unit; 313: third light-emitting unit; 314: fourth light-emitting unit; 315: fifth light-emitting unit; 320: first pixel column; 330: second pixel column; 340: third pixel column; 350: first pixel group; 360: second pixel group; 370: pixel cell;
400: second electrode layer; 410: second electrode;
500: pixel definition layer; 510: pixel limiting portion; 511: first portion; 512: second portion; 520: pixel opening; 530: first electrode;
600: first encapsulation layer; 610: encapsulation portion; 611: extension portion;
D1: first sub-width; D2: second sub-width; D3: third sub-width; D4: fourth sub-width; D5: fifth sub-width; D6: sixth sub-width; D7: seventh sub-width;
X: first direction; Y: second direction.

### DETAILED DESCRIPTION OF THE EMBODIMENTS

The application will be further described in detail below with reference to the accompanying drawings and specific embodiments.

It should be understood that when describing the structure of a component, if one layer or region is referred to as being “on” or “above” another layer or region, it may mean being directly on the other layer or region, or there may be an intervening layer or region between them. Moreover, if the component is flipped, the one layer or region will be “under” or “below” the other layer or region.

The embodiments of the present application provide a display panel and a display device. Various embodiments of the display panel and the display device will be described below with reference to the accompanying drawings.

An embodiment of the present application provides a display panel. The display panel may be an Organic Light Emitting Diode (OLED) display panel.

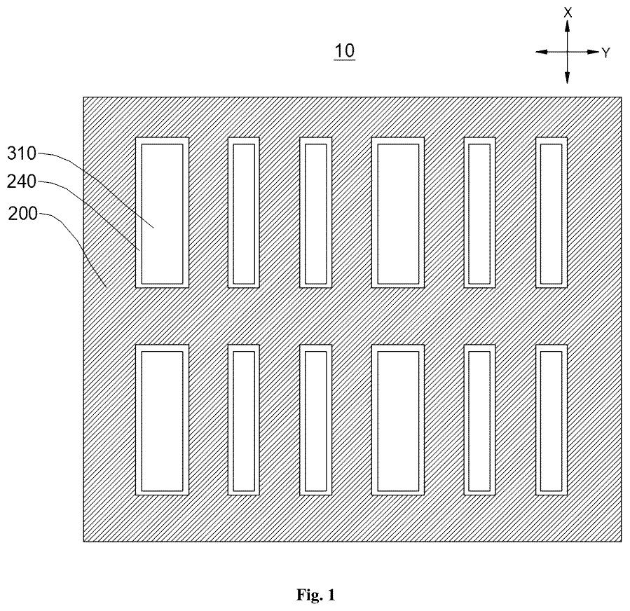

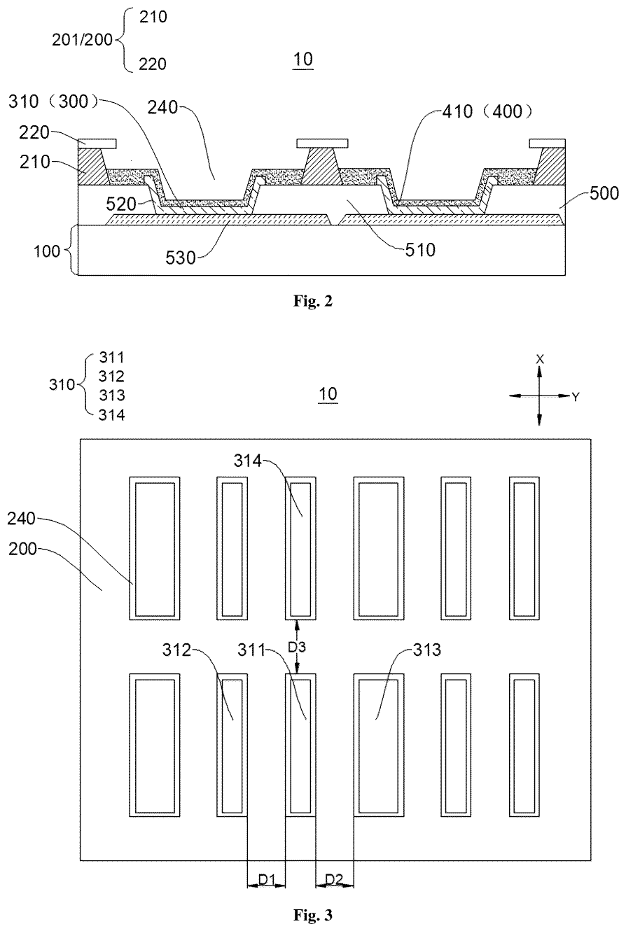

Referring to FIGS. 1 to 3, FIG. 1 is a partial top view schematic diagram of a display panel provided by an embodiment of the present application; FIG. 2 is a partial cross-sectional view of a display panel provided by an embodiment of the present application; FIG. 3 is a partial top view schematic diagram of a display panel in another embodiment.

As shown in FIGS. 1 to 3, the first aspect of the present application provides a display panel 10, which includes: a substrate 100; an isolation layer 200 that is located on a side of the substrate 100 and includes an isolation structure 201 and a plurality of isolation openings 240 enclosed by the isolation structure 201; a light-emitting layer 300 that is located on a side of the substrate 100 and includes a plurality of light-emitting units 310. At least part of the light-emitting unit 310 is located in the isolation opening 240. The plurality of the light-emitting units 310 are arranged along the intersecting first direction X and second direction Y. The light-emitting units 310 include a first light-emitting unit 311, a second light-emitting unit 312 and a third light-emitting unit 313 adjacent to the first light-emitting unit 311 in the second direction Y, and a fourth light-emitting unit 314 adjacent to the first light-emitting unit 311 in the first direction X. The width of the isolation structure 201 between the first light-emitting unit 311 and the second light-emitting unit 312 is a first sub-width D1, the width of the isolation structure 201 between the first light-emitting unit 311 and the third light-emitting unit 313 is a second sub-width D2, and the width of the isolation structure 201 between the first light-emitting unit 311 and the fourth light-emitting unit 314 is a third sub-width D3. The sum of the first sub-width D1 and the second sub-width D2 is less than the third sub-width D3, and the first direction X and the second direction Y intersect.

The width of the isolation structure 201 refers to the maximum dimension of the isolation structure 201 in the direction from one isolation opening 240 to the other adjacent isolation opening 240 of two isolation openings at two sides of the isolation structure 201.

According to the display panel 10 of the embodiment of the present application, the display panel 10 includes a substrate 100, an isolation layer 200, and a light-emitting layer 300. The isolation structures 201 of the isolation layer 200 enclose the isolation openings 240, and at least a portion of the light-emitting unit 310 of the light-emitting layer 300 is located in the isolation opening 240, which can alleviate the issue of light interference between adjacent light-emitting units 310. The multiple light-emitting units 310 are arranged along the intersecting first direction X and second direction Y, and the light-emitting units 310 include a first light-emitting unit 311, a second light-emitting unit 312 and a third light-emitting unit 313 adjacent to the first light-emitting unit 311 in the second direction Y, and a fourth light-emitting unit 314 adjacent to the first light-emitting unit 311 in the first direction X. The width of the isolation structure 201 between the first light-emitting unit 311 and the second light-emitting unit 312 is a first sub-width D1, the width of the isolation structure 201 between the first light-emitting unit 311 and the third light-emitting unit 313 is a second sub-width D2, and the width of the isolation structure 201 between the first light-emitting unit 311 and the fourth light-emitting unit 314 is a third sub-width D3. That is, the width of the isolation structure 201 between the first light-emitting unit 311 and the fourth light-emitting unit 314 adjacent to each other in the first direction X is larger, which makes it possible to reduce the resistance of the isolation structure 201 extending in the second direction Y, reduce the voltage drop of the isolation structure 201, and thus reduce the overall power consumption of the display panel 10 and improve the performance of OLED display products.

As shown in FIG. 2, in some embodiments, the display panel 10 further includes: a pixel definition layer 500 that is located on a side of the substrate 100 and includes a pixel limiting portion 510 and pixel openings 520 enclosed by the pixel limiting portion 510. At least some of the pixel openings 520 correspond to and communicate with the isolation openings 240 in a one-to-one correspondence. For the display area of the display panel 10, the pixel openings 520 correspond to and communicate with the isolation openings 240 in a one-to-one correspondence.

In these embodiments, the pixel limiting portion 510 of the pixel definition layer 500 encloses the pixel openings 520 to set the light-emitting units 310, allowing the light-emitting units 310 to emit light normally. Moreover, the pixel limiting portion 510 defines the light-emitting regions of the light-emitting units 310, reducing color bleeding between the light-emitting units 310.

In some embodiments, the second light-emitting unit 312 and the third light-emitting unit 313 are located on two sides of the first light-emitting unit 311.

In these embodiments, when the second light-emitting unit 312 and the third light-emitting unit 313 are located on different sides of the first light-emitting unit 311, the sum of the first sub-width D1 and the second sub-width D2 is less than the third sub-width D3. That is, the width of the isolation structure 201 between the first light-emitting unit 311 and the fourth light-emitting unit 314 adjacent to each other in the first direction X is larger, which makes it possible to reduce the resistance of the isolation structure 201 extending in the second direction Y, reduce the voltage drop of the isolation structure 201, and thus reduce the overall power consumption of the display panel 10.

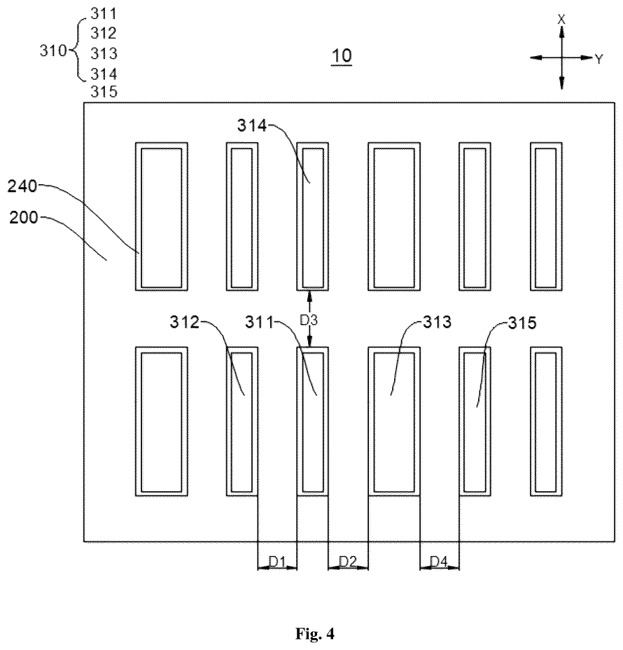

Please refer to FIG. 4, which is a partial top view schematic diagram of a display panel in another embodiment.

As shown in FIG. 4, in some embodiments, the light-emitting units 310 may also include a fifth light-emitting unit 315 arranged in a same row as the first light-emitting unit 311, the second light-emitting unit 312, and the third light-emitting unit 313 along the second direction Y. The width of the isolation structure 201 between the fifth light-emitting unit 315 and the third light-emitting unit 313 is a fourth sub-width D4. At least one of the sum of the fourth sub-width D4 and the first sub-width D1 or the sum of the fourth sub-width D4 and the second sub-width D2 is less than the third sub-width D3.

In these embodiments, the sum of the fourth sub-width D4 and the second sub-width D2 is less than the third sub-width D3; or the sum of the fourth sub-width D4 and the first sub-width D1 is less than the third sub-width D3, and the sum of the fourth sub-width D4 and the second sub-width D2 is also less than the third sub-width D3. This arrangement results in a larger width of the isolation structure 201 between the first light-emitting unit 311 and the fourth light-emitting unit 314 adjacent to each other in the first direction X, which makes it possible to reduce the resistance of the isolation structure 201 extending in the second direction Y, reduce the voltage drop of the isolation structure 201, and thus reduce the overall power consumption of the display panel 10.

The third sub-width D3 is greater than at least one of the first sub-width D1, the second sub-width D2, or the fourth sub-width D4. This ensures that the width of the isolation structure 201 between the first light-emitting unit 311 and the fourth light-emitting unit 314 adjacent to each other in the first direction X is larger, thereby reducing the resistance of the isolation structure 201 extending in the second direction Y, reducing the voltage drop of the isolation structure 201, and thus reducing the overall power consumption of the display panel 10.

In some embodiments, the third sub-width D3 is less than the sum of the first sub-width D1, the second sub-width D2, and the fourth sub-width D4.

In these embodiments, it is ensured that the third sub-width D3 is less than the sum of the first sub-width D1, the second sub-width D2, and the fourth sub-width D4, so that it is possible to avoid the issue of the third sub-width D3 being too large, leading to a too small area for the isolation openings 240 on two sides of the isolation structure 201 having a too large width, and resulting in a reduced opening ratio of the light-emitting unit 310 and a decreased display effect of the display panel 10. That is, it is possible to mitigate the impact of a too large third sub-width D3 on the opening ratio.

The second light-emitting unit 312 and the fifth light-emitting unit 315 have the same luminous color, meaning that multiple first light-emitting units 311, multiple second light-emitting units 312, and multiple third light-emitting units 313 are arranged alternately in the second direction Y.

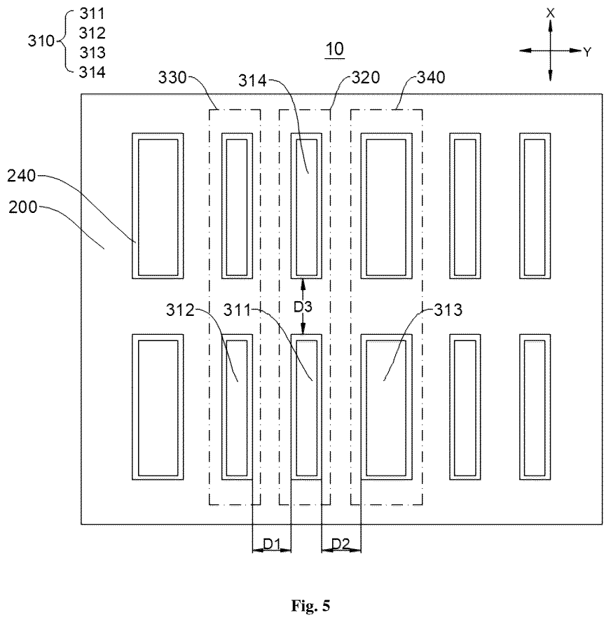

Please refer to FIG. 5, which is a partial top view schematic diagram of a display panel in another embodiment.

As shown in FIG. 5, in some embodiments, multiple first light-emitting units 311 and multiple fourth light-emitting units 314 are arranged along the first direction X to form a first pixel column 320, multiple second light-emitting units 312 are arranged along the first direction X to form a second pixel column 330, and multiple third light-emitting units 313 are arranged along the first direction X to form a third pixel column 340. The first pixel column 320, the second pixel column 330, and the third pixel column 340 are arranged alternately along the second direction Y.

In these embodiments, the width of the isolation structure 201 between the adjacent first light-emitting unit 311 and fourth light-emitting unit 314 in the first pixel column 320 is the third sub-width D3. In the adjacent first pixel column 320 and second pixel column 330, the width of the isolation structure 201 between the first light-emitting unit 311 of the first pixel column 320 and the second light-emitting unit 312 of the second pixel column 330 is the first sub-width D1. In the adjacent first pixel column 320 and third pixel column 340, the width of the isolation structure 201 between the first light-emitting unit 311 of the first pixel column 320 and the third light-emitting unit 313 of the third pixel column 340 is the second sub-width D2. The sum of the first sub-width D1 and the second sub-width D2 is less than the third sub-width D3, which makes it possible to reduce the resistance of the isolation structure 201 located between the first light-emitting unit 311 and the fourth light-emitting unit 314 and extending in the second direction Y, reduce the voltage drop of the isolation structure 201, and thus reduce the overall power consumption of the display panel 10.

The luminous colors of the first light-emitting unit 311, the second light-emitting unit 312, and the third light-emitting unit 313 are different. For example, the luminous color of the first light-emitting unit 311 is red, the luminous color of the second light-emitting unit 312 is green, and the luminous color of the third light-emitting unit 313 is blue. In other embodiments, the luminous color of the first light-emitting unit 311 can also be blue or green, the luminous color of the second light-emitting unit 312 can also be red or blue, and the luminous color of the third light-emitting unit 313 can also be red or green.

The luminous colors of the first light-emitting unit 311 and the fourth light-emitting unit 314 are the same, meaning that multiple first light-emitting units 311 of the same color are arranged along the first direction X to form the first pixel column 320. The width of the isolation structure 201 between adjacent first light-emitting units 311 is the third sub-width D3. The resistance of the isolation structure 201 located between adjacent first light-emitting units 311 and extending in the second direction Y is reduced, the voltage drop of the isolation structure 201 is reduced, and thus the overall power consumption of the display panel 10 is reduced.

Additionally, when the luminous colors of the first light-emitting unit 311 and the fourth light-emitting unit 314 are the same and the luminous colors of the second light-emitting unit 312 and the fifth light-emitting unit 315 are the same, multiple first light-emitting units 311 of the same color are arranged along the first direction X to form the first pixel column 320, multiple second light-emitting units 312 of the same color are arranged along the first direction X to form the second pixel column 330, and multiple third light-emitting units 313 of the same color are arranged along the first direction X to form the third pixel column 340. The first pixel column 320, the second pixel column 330, and the third pixel column 340 are arranged alternately along the second direction Y. This pixel arrangement structure is simple and easy to fabricate.

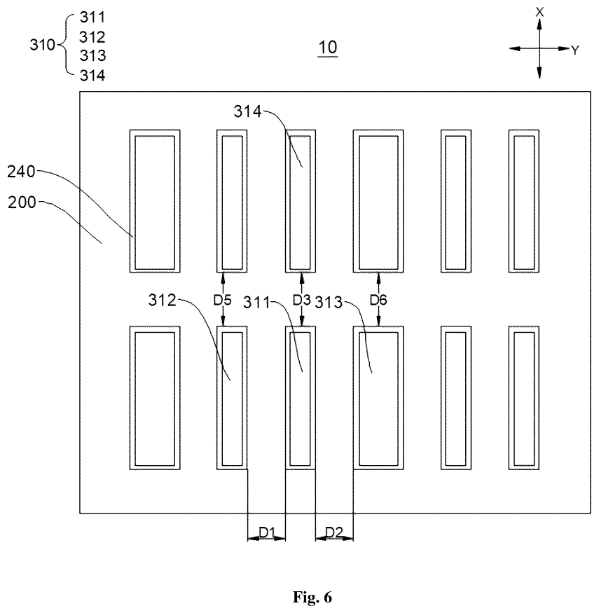

Please refer to FIG. 6, which is a partial top view schematic diagram of a display panel in another embodiment.

As shown in FIG. 6, in some embodiments, the width of the isolation structure 201 between adjacent second light-emitting units 312 is the fifth sub-width D5, and the third sub-width D3 is equal to the fifth sub-width D5.

In these embodiments, the third sub-width D3 is equal to the fifth sub-width D5, meaning that the width of the isolation structure 201 between the adjacent first light-emitting unit 311 and fourth light-emitting unit 314 is equal to the width of the isolation structure 201 between two adjacent second light-emitting units 312. This arrangement increases the width of the isolation structure 201 between two adjacent second light-emitting units 312, reduces the resistance of the isolation structure 201 located between two adjacent second light-emitting units 312 and extending in the second direction Y, reduces the voltage drop of the isolation structure 201, and thus reduces the overall power consumption of the display panel 10.

In some embodiments, the width of the isolation structure 201 between two adjacent third light-emitting units 313 is the sixth sub-width D6, and the third sub-width D3 is equal to the sixth sub-width D6.

In these embodiments, the third sub-width D3 is equal to the sixth sub-width D6, meaning that the width of the isolation structure 201 between the adjacent first light-emitting unit 311 and fourth light-emitting unit 314 is equal to the width of the isolation structure 201 between two adjacent third light-emitting units 313. This arrangement increases the width of the isolation structure 201 between two adjacent third light-emitting units 313, reduces the resistance of the isolation structure 201 located between two adjacent third light-emitting units 313 and extending in the second direction Y, reduces the voltage drop of the isolation structure 201, and thus reduces the overall power consumption of the display panel 10.

The third sub-width D3, the fifth sub-width D5, and the sixth sub-width D6 are all equal, making the arrangement of the light-emitting units 310 more uniform, improving the display effect of the display panel 10, and further reducing the overall resistance of the isolation structure 201, thus reducing the overall power consumption of the display panel 10.

In some embodiments, an area of an orthographic projection of the third light-emitting unit 313 on the substrate 100 is greater than or equal to an area of an orthographic projection of the first light-emitting unit 311 on the substrate 100, and/or the area of the area of the orthographic projection of the third light-emitting unit 313 on the substrate 100 is greater than or equal to an area of an area of the orthographic projection of the second light-emitting unit 312 on the substrate 100.

The area of the orthographic projection of the third light-emitting unit 313 on the substrate 100 is greater than or equal to the area of the orthographic projection of the first light-emitting unit 311 on the substrate 100; or the area of the orthographic projection of the third light-emitting unit 313 on the substrate 100 is greater than or equal to the area of the orthographic projection of the second light-emitting unit 312 on the substrate 100; or the area of the orthographic projection of the third light-emitting unit 313 on the substrate 100 is greater than or equal to the area of the orthographic projection of the first light-emitting unit 311 on the substrate 100, and the area of the orthographic projection of the third light-emitting unit 313 on the substrate 100 is greater than or equal to the area of the orthographic projection of the second light-emitting unit 312 on the substrate 100.

In these embodiments, the color of the third light-emitting unit 313 can be blue. The larger area of the third light-emitting unit 313 can improve the service life of the third light-emitting unit 313 and avoid the problem that the rapid decay of the brightness of the third light-emitting unit 313 leads to a decrease in the display effect of the display panel 10.

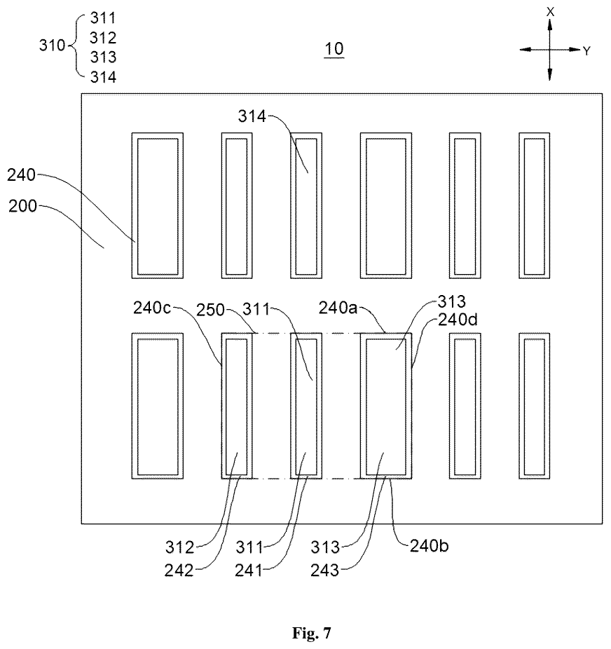

Please refer to FIG. 7, which is a partial top view schematic diagram of a display panel in another embodiment.

As shown in FIG. 7, in some embodiments, the isolation openings 240 include a first isolation opening 241, a second isolation opening 242, and a third isolation opening 243. At least a portion of the first light-emitting unit 311 is located within the first isolation opening 241, at least a portion of the second light-emitting unit 312 is located within the second isolation opening 242, and at least a portion of the third light-emitting unit 313 is located within the third isolation opening 243. The orthographic projections of the adjacent first isolation opening 241, second isolation opening 242, and third isolation opening 243 on the substrate 100 are located within the same virtual quadrilateral 250. In FIG. 7, the position of the virtual quadrilateral 250 is indicated by the dashed line, but the dashed line does not constitute a limitation on the structure of the display panel 10 of the embodiment of the present application.

In these embodiments, the adjacent first isolation opening 241, second isolation opening 242, and third isolation opening 243 are set within the same virtual quadrilateral 250, and multiple virtual quadrilaterals 250 are arranged repeatedly to form the isolation openings 240 on the entire display panel. This arrangement improves the uniformity of the distribution of the isolation openings 240 and thus improves the display effect of the display panel 10. The arrangement of the first isolation opening 241, the second isolation opening 242, and the third isolation opening 243 being set within the virtual quadrilateral 250 makes the first isolation opening 241, the second isolation opening 242, and the third isolation opening 243 more regularly distributed and easier to fabricate.

In some embodiments, the orthographic projection of the isolation opening 240 on the substrate 100 has a first side 240a and a second side 240b that are oppositely set in the first direction X. The first side 240a and the second side 240b of each of the first isolation opening 241, second isolation opening 242, and third isolation opening 243 coincide with the sides of the virtual quadrilateral 250.

In these embodiments, the first side 240a and the second side 240b of each of the first isolation opening 241, second isolation opening 242, and third isolation opening 243 coincide with the sides of the virtual quadrilateral 250, meaning that the first sides 240a of the first isolation opening 241, second isolation opening 242, and third isolation opening 243 are on the same straight line, and the second sides 240b of the first isolation opening 241, second isolation opening 242, and third isolation opening 243 are on the same straight line. The first isolation opening 241, second isolation opening 242, and third isolation opening 243 are arranged side by side and aligned in the second direction Y, making the distribution of the first isolation opening 241, second isolation opening 242, and third isolation opening 243 more uniform and further improving the display effect of the display panel 10.

The orthographic projection of the isolation opening 240 on the substrate 100 has a third side 240c and a fourth side 240d that are oppositely set in the second direction Y. The third side 240c of the second isolation opening 242 and the fourth side 240d of the third isolation opening 243 coincide with the sides of the virtual quadrilateral 250, which improves the uniformity of the distribution of the first isolation opening 241, second isolation opening 242, and third isolation opening 243.

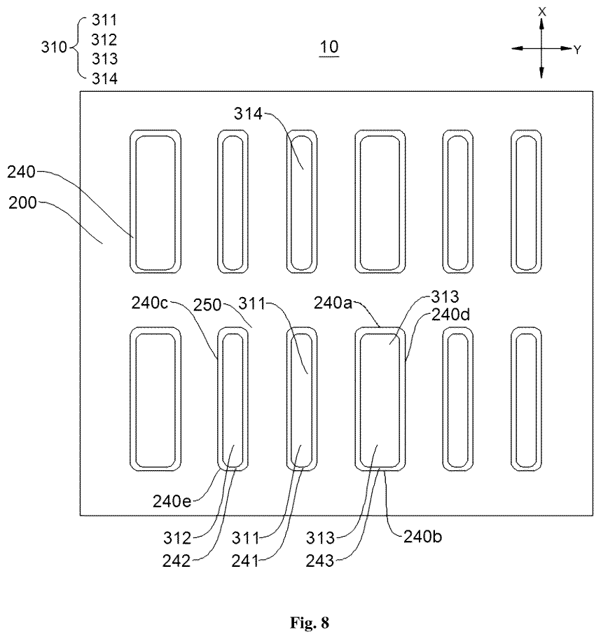

Please refer to FIG. 8, which is a partial top view schematic diagram of a display panel in another embodiment.

As shown in FIG. 8, in some embodiments, the orthographic projection of the isolation opening 240 on the substrate 100 also has four arc edges 240e each located between either two sides of the first side 240a, the second side 240b, the third side 240c, and the fourth side 240d, to form a rounded rectangle.

In these embodiments, an arc edge 240e is set between either two adjacent sides of the first side 240a, the second side 240b, the third side 240c, and the fourth side 240d, making the transition between adjacent sides smooth and easier to fabricate.

The virtual quadrilateral 250 is a rectangle, which further improves the uniformity of the distribution of the first isolation opening 241, the second isolation opening 242, and the third isolation opening 243, and further improves the display effect of the display panel 10.

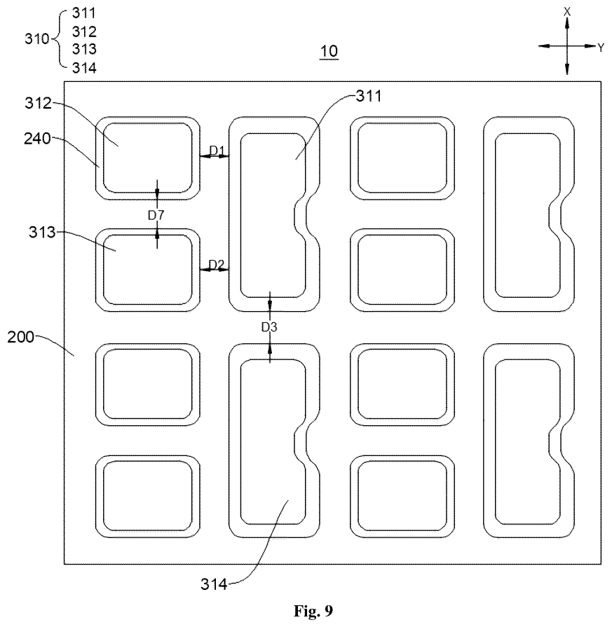

Please refer to FIG. 9, which is a partial top view schematic diagram of a display panel in another embodiment.

As shown in FIG. 9, in some embodiments, the second light-emitting unit 312 and the third light-emitting unit 313 are located on the same side of the first light-emitting unit 311.

In these embodiments, when the second light-emitting unit 312 and the third light-emitting unit 313 are located on the same side of the first light-emitting unit 311, the sum of the first sub-width D1 and the second sub-width D2 is less than the third sub-width D3. That is, the width of the isolation structure 201 between the adjacent first light-emitting unit 311 and fourth light-emitting unit 314 in the first direction X is larger, and it is possible to reduce the resistance of the isolation structure 201 located between the first light-emitting unit 311 and the fourth light-emitting unit 314 and extending in the second direction Y, reduce the voltage drop of the isolation structure 201, and thus reduce the overall power consumption of the display panel 10.

Additionally, when the second light-emitting unit 312 and the third light-emitting unit 313 are located on the same side of the first light-emitting unit 311, it is possible to reduce the spacing between the second light-emitting unit 312 and the third light-emitting unit 313, reduce the spacing between the light-emitting units 310 of different colors used to form the display unit, and thus improve the display effect.

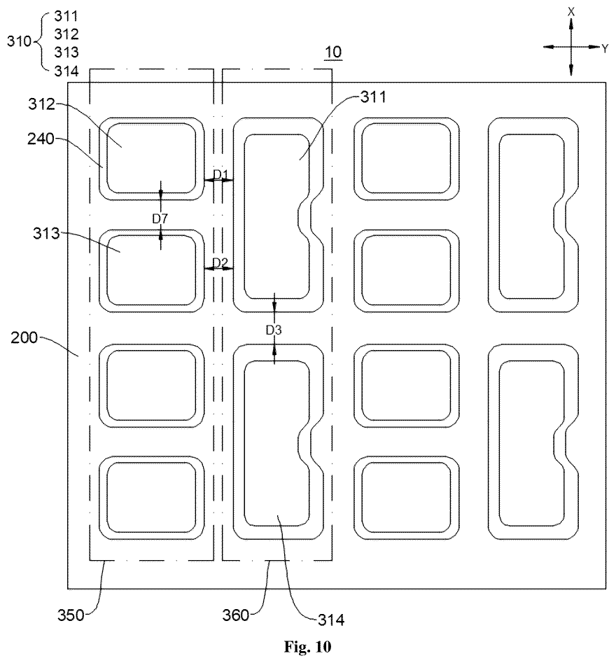

Please refer to FIG. 10, which is a partial top view schematic diagram of a display panel in another embodiment.

As shown in FIG. 10, in some embodiments, multiple second light-emitting units 312 and multiple third light-emitting units 313 are alternately arranged along the first direction X to form a first pixel group 350, and multiple first light-emitting units 311 and multiple fourth light-emitting units 314 are arranged along the first direction X to form a second pixel group 360. The first pixel group 350 and the second pixel group 360 are alternately arranged along the second direction Y.

In these embodiments, in the adjacent first pixel group 350 and second pixel group 360, the width of the isolation structure 201 between the first light-emitting unit 311 in the second pixel group 360 and the second light-emitting unit 312 located on a side of the first light-emitting unit 311 in the second direction Y is the first sub-width D1. The width of the isolation structure 201 between the same first light-emitting unit 311 and the third light-emitting unit 313 located on the same side of the first light-emitting unit 311 in the second direction Y is the second sub-width D2. The sum of the first sub-width D1 and the second sub-width D2 is less than the third sub-width D3, which makes it possible to reduce the resistance of the isolation structure 201 located between the first light-emitting unit 311 and the fourth light-emitting unit 314 and extending in the second direction Y, reduce the voltage drop of the isolation structure 201, and thus reduce the overall power consumption of the display panel 10.

Within the same first pixel group 350, the width of the isolation structure 201 between the adjacent second light-emitting unit 312 and third light-emitting unit 313 located on a side of the same first light-emitting unit 311 is the seventh sub-width D7. The seventh sub-width D7 is greater than the sum of the first sub-width D1 and the second sub-width D2, which makes it possible to reduce the resistance of the isolation structure 201 extending in the second direction Y and located between the second light-emitting unit 312 and the third light-emitting unit 313 on the same side of the same first light-emitting unit 311, reduce the voltage drop of the isolation structure 201, and thus reduce the overall power consumption of the display panel 10.

As mentioned above, the luminous colors of the first light-emitting unit 311, the second light-emitting unit 312, and the third light-emitting unit 313 are different. For example, the luminous color of the first light-emitting unit 311 is blue, the luminous color of the second light-emitting unit 312 is green, and the luminous color of the third light-emitting unit 313 is red.

As mentioned above, the luminous colors of the fourth light-emitting unit 314 and the first light-emitting unit 311 are the same.

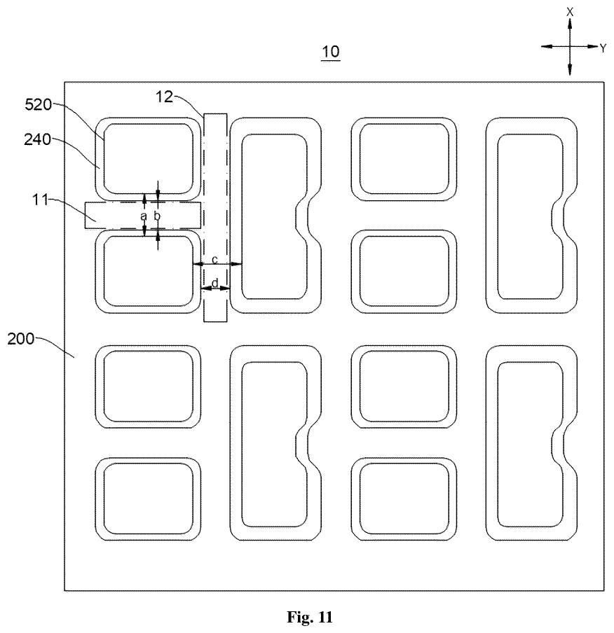

Please refer to FIGS. 2 and 11 together. FIG. 11 is a partial top view schematic diagram of a display panel in another embodiment.

As shown in FIGS. 2 and 11, in some embodiments, there are a first region 11 and a second region 12 between adjacent light-emitting units 310. The width of the isolation structure 201 in the first region 11 is greater than the width of the isolation structure 201 in the second region 12, and the width of the pixel limiting portion 510 in the first region 11 is greater than the width of the pixel limiting portion 510 in the second region 12.

The width of the pixel limiting portion 510 refers to the maximum dimension of the pixel limiting portion 510 in the direction from one pixel opening 520 to the other adjacent pixel opening 520 of two pixel openings 520 at two sides of the pixel limiting portion 510.

In these embodiments, within the first region 11 where the pixel limiting portion 510 has a larger width, the width of the isolation structure 201 is set to be larger, realizing a differentiated design of the width of the isolation structure 201 in the first region 11 and the second region 12. This reduces the resistance of the isolation structure 201 in the first region 11, thereby reducing the voltage drop of the isolation structure 201 and thus reducing the overall power consumption of the display panel 10. For example, if the width of the pixel limiting portion 510 in the first region 11 is a, the width of the isolation structure 201 is b, the width of the pixel limiting portion 510 in the second region 12 is c, and the width of the isolation structure 201 is d, then when a is greater than c, b is greater than d, which makes the width of the isolation structure 201 more adaptable to the width of the pixel limiting portion 510. It is also ensured that the spacing from the edge of the pixel opening 520 to the edge of the isolation opening 240 is the same in different regions, making the impact of the isolation structure 201 on the light emission of different light-emitting units 310 more consistent, and improving the display uniformity of the display panel 10.

In some embodiments, the ratio of the width of the isolation structure 201 to the width of the pixel limiting portion 510 in the first region 11 is greater than or equal to the ratio of the width of the isolation structure 201 to the width of the pixel limiting portion 510 in the second region 12. For example, b/a is greater than d/c.

In these embodiments, the ratio of the width of the isolation structure 201 to the width of the pixel limiting portion 510 in the first region 11 is set to be larger than that in the second region 12. Furthermore, since the width of the pixel limiting portion 510 in the first region 11 is greater than the width of the pixel limiting portion 510 in the second region 12, the width of the isolation structure 201 in the first region 11 is further increased, realizing a maximized design of the width of the isolation structure 201 in the first region 11. This further reduces the resistance of the isolation structure 201 in the first region 11, thereby reducing the voltage drop of the isolation structure 201 and thus reducing the overall power consumption of the display panel 10.

The width of the isolation structure 201 in the first region 11 is greater than or equal to 1.5 times the width of the isolation structure 201 in the second region 12. For example, the width of the isolation structure 201 in the first region 11 is 1.5 times, 2.0 times, 2.2 times, 2.3 times, 3 times, etc. of the width of the isolation structure 201 in the second region 12. The width of the isolation structure 201 in the first region 11 is further increased, thereby further reducing the resistance of the isolation structure 201 in the first region 11, reducing the voltage drop of the isolation structure 201, and thus reducing the overall power consumption of the display panel 10.

The ratio of the width of the isolation structure 201 to the width of the pixel limiting portion 510 between two adjacent light-emitting units 310 is greater than or equal to 0.5, so as to alleviate the issue that the ratio of the width of the isolation structure 201 to the width of the pixel limiting portion 510 is too small, which leads to the width of the isolation structure 201 being too small, and results in a large resistance and a large voltage drop of the isolation structure 201 and thus a large overall power consumption of the display panel 10. It is also possible to alleviate the issue that the ratio of the width of the isolation structure 201 to the width of the pixel limiting portion 510 is too small and the spacing between the edge of the pixel opening 520 and the edge of the isolation opening 240 is too large, which impacts the light emission effect.

In this embodiment, the pixel arrangement, the isolation structure, the pixel definition layer, and other structures are set in accordance with the above embodiments. The first sub-width, the second sub-width, and the fourth sub-width in the above embodiments are the widths of the isolation structures 201 in the second region 12, and the third sub-width and the fifth sub-width in the above embodiments are the widths of the isolation structures 201 in the first region 11. It can be understood that some parts of the isolation structure 201 may be divided into multiple first regions and multiple second regions, and the width of the isolation structure mentioned above refers to the width of the isolation structure corresponding to one first region or one second region.

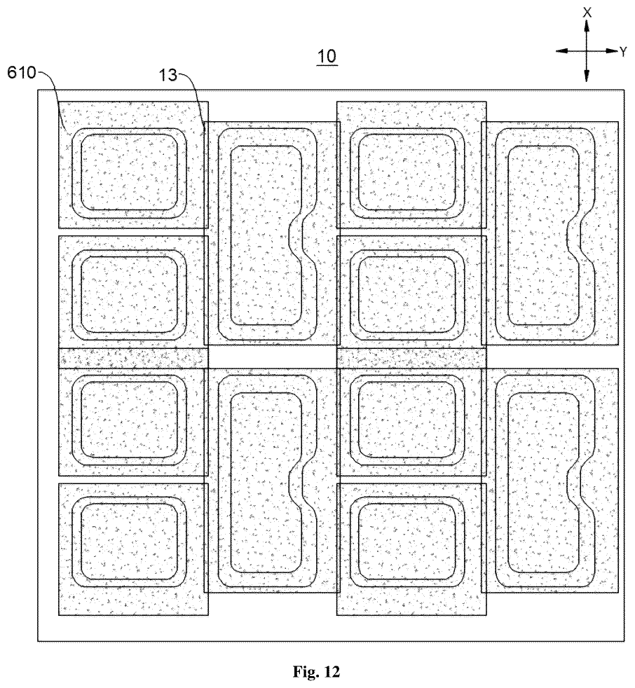

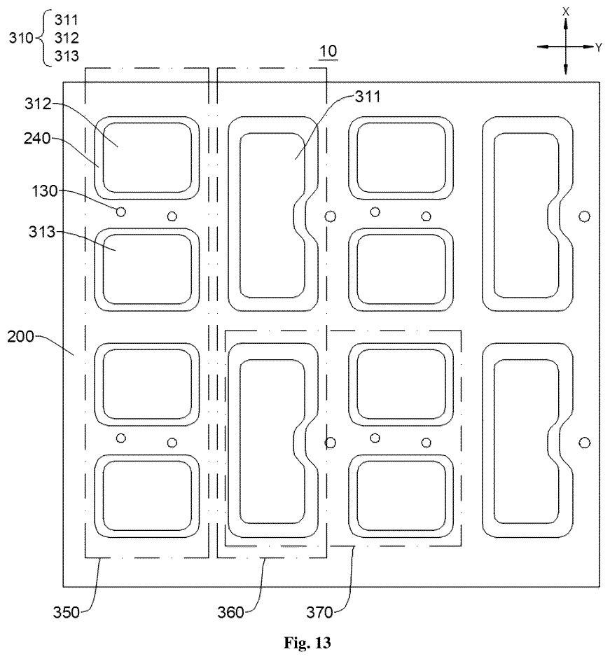

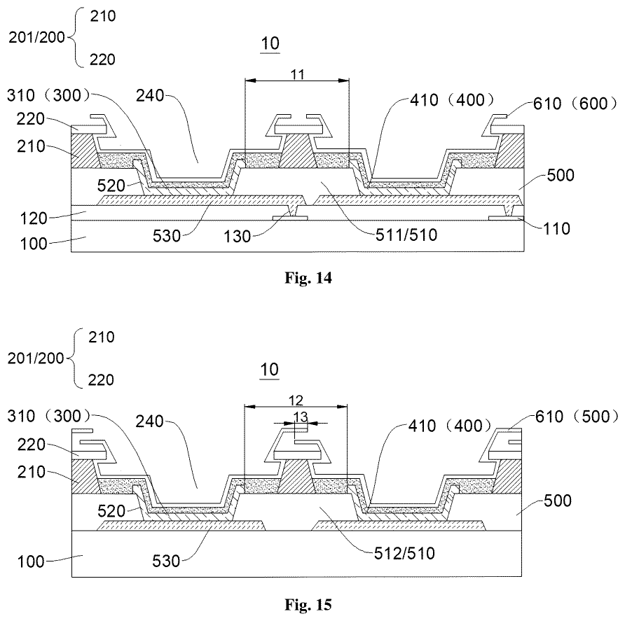

Please refer to FIGS. 12 to 15 together. FIG. 12 is a partial top view schematic diagram of a display panel in another embodiment; FIG. 13 is a partial top view schematic diagram of a display panel in another embodiment; FIG. 14 is a partial cross-sectional view of a display panel in another embodiment; FIG. 15 is a partial cross-sectional view of a display panel in another embodiment.

As shown in FIGS. 12 to 15, in some embodiments, the display panel 10 further includes: a first encapsulation layer 600, located on a side of the light-emitting layer 300 facing away from the substrate 100. The first encapsulation layer 600 includes a plurality of encapsulation portions 610 each for encapsulating a corresponding light-emitting unit 310. The orthographic projections of at least two adjacent encapsulation portions 610 on the substrate 100 overlap to form an overlapping region 13. There are a first region 11 and a second region 12 between adjacent light-emitting units 310, the width of the isolation structure 201 in the first region 11 is greater than the width of the isolation structure 201 in the second region 12, the overlapping region 13 is located outside of the orthographic projection of the isolation structure 201 in the first region 11 on the substrate 100, and the overlapping region 13 is located within the orthographic projection of the isolation structure 201 in the second region 12 on the substrate 100.

In these embodiments, the width of the isolation structure 201 in the first region 11 is greater than the width of the isolation structure 201 in the second region 12, which increases the width of the isolation structure 201 in the first region 11, reduces the resistance of the isolation structure 201 in the first region 11, reduces the voltage drop of the isolation structure 201, and thus reduces the overall power consumption of the display panel 10. The overlapping region 13 is located outside of the orthographic projection of the isolation structure 201 in the first region 11 on the substrate 100. In the first region 11, the orthographic projections of two adjacent encapsulation portions 610 on the substrate 100 are spaced apart. That is, the width of the isolation structure 201 corresponding to the spacing between the two encapsulation portions 610 is larger, which makes the spacing between the two adjacent encapsulation portions 610 larger is beneficial for subsequent filling a second encapsulation layer made of organic material between the encapsulation portion 610 and the isolation structure 201, thereby improving the encapsulation effect. The overlapping region 13 is located within the orthographic projection of the isolation structure 201 in the second region 12. In the second region 12, the orthographic projections of two adjacent encapsulation portions 610 on the substrate 100 overlap. That is, the width of the isolation structure 201 corresponding to the overlapping region 13 of the two encapsulation portions 610 is smaller, which makes the width of the two overlapping encapsulation portions 610 on a side of the isolation structure 201 facing away from the substrate 100 smaller, and makes it possible to avoid the problem of parts of the two overlapping encapsulation portions 610 on the side of the isolation structure 201 facing away from the substrate 100 being too wide, leading to the parts of the encapsulation portions 610 on the side of the isolation structure 201 facing away from the substrate 100 being prone to fracture under force.

In some embodiments, the ratio of the width of the overlapping region 13 to the width of the isolation structure 201 in the second region 12 is less than or equal to 0.5, e.g. 0.5, 0.4, 0.3/0.2, 0.1, etc.

In these embodiments, the ratio of the width of the overlapping region 13 to the width of the isolation structure 201 in the second region 12 being less than or equal to 0.5 can avoid the problem of the overlapping region 13 being too wide, the parts of the two overlapping two encapsulation portions 610 on the side of the isolation structure 201 facing away from the substrate 100 being too wide, and leading to the parts of the encapsulation portions 610 on the side of the isolation structure 201 facing away from the substrate 100 being prone to fracture under force.

The width of the isolation structure 201 is 3 μm to 26 μm. For example, the width of the orthographic projection of the isolation structure 201 on the substrate 100 is 3 μm, 4 μm, 5 μm, 15 μm, 18 μm, 26 μm, etc.

In these embodiments, the width of the isolation structure 201 being greater than or equal to 3 μm can alleviate the problem that the isolation structure 201 having a too small width leads to a large resistance and an increased voltage drop of the isolation structure 201, and an increased power consumption of the display panel 10. It is also possible to alleviate the problem that the isolation structure 201 having a too small width leads to a small spacing between the two encapsulation portions 610 spaced apart in the first region 11 and thus it is difficult to perform filling and encapsulating with the second encapsulation layer made of organic material. The width of the isolation structure 201 being less than or equal to 26 μm can alleviate the problem that the isolation structure 201 having a too large width results in a low opening ratio.

As shown in FIG. 14, in some embodiments, the display panel 10 further includes a drive circuit 110, a first insulating layer 120, and a first electrode 530 stacked in the direction away from the substrate 100. The first electrode 530 is located on the side of the light-emitting unit 310 facing the substrate 100 and is exposed by the isolation opening 240. The first insulating layer 120 has a via 130, and at least a portion of the first electrode 530 is located in the via 130 and electrically connected to the drive circuit 110. The orthographic projection of the via 130 on the substrate 100 overlaps the orthographic projection of the isolation structure 201 in the first region 11 on the substrate 100.

The first insulating layer 120 includes a planarization layer, and the via 130 is formed in the planarization layer.

In these embodiments, the first electrode 530 is electrically connected to the drive circuit 110 through the via 130 in the first insulating layer 120 to realize the signal control for the first electrode 530 by the drive circuit 110, and the first electrode 530 is exposed by the isolation opening 240, allowing the first electrode 530 to contact the light-emitting unit 310 and serve as an electrode for the light-emitting unit 310 to control the light emission of the light-emitting unit 310. The via 130 is set in the first region 11. Due to the larger width of the isolation structure 201 in the first region 11, the first region 11 has a larger layout space, facilitating the setting of the via 130. Therefore, setting the via 130 in the first region 11 can reduce the difficulty of setting the via 130. Moreover, the orthographic projection of the via 130 on the substrate 100 overlapping the orthographic projection of the isolation structure 201 on the substrate 100 can reduce the overlapping area between the orthographic projection of the via 130 on the substrate 100 and the orthographic projection of the second electrode 410 or the light-emitting unit 310 on the substrate 100, thereby alleviating the problem that the overlapping between the orthographic projection of the via 130 on the substrate 100 and the orthographic projection of the second electrode 410 or the light-emitting unit 310 on the substrate 100 and an uneven surface of the second electrode 410 or the light-emitting unit 310 may impact the light emission of the light-emitting unit 310 and the display effect of the display panel 10.

In the first region 11, the orthographic projection of the drive circuit 110 on the substrate 100 is located outside of the orthographic projection of the encapsulation portion 610 on the substrate 100. That is, the drive circuit 110 in the first region 11 is set in an area outside of the encapsulation portion 610, which avoids the problem that the drive circuit 110 in the first region 11 is set below the encapsulation portion 610, i.e., the orthographic projection of the drive circuit 110 on the substrate 100 overlaps the encapsulation portion 610, causing the encapsulation portion 610 to deform and be prone to fracture.

As shown in FIGS. 14 and 15, in some embodiments, the pixel definition layer 500 includes a first portion 511 and a second portion 512. The width of the pixel limiting portion 510 in the first region 11 is greater than the width of the pixel limiting portion 510 in the second region 12. The first portion 511 is located in the first region 11, and the second portion 512 is located in the second region 12. The width of the first electrode 530 on the side of the first portion 511 is greater than or equal to the width of the first electrode 530 on the side of the second portion 512.

In these embodiments, the first portion 511 is wider than the second portion 512, and the pixel limiting portion 510 in the first region 11 is set to be wider, facilitating the setting of a wider isolation structure 201 on the pixel limiting portion 510 to reduce the resistance of the isolation structure 201. Increasing the width of the first electrode 530 extending into the first portion 511 increases the overall area of the first electrode 530, and reduces the resistance and the power consumption of the first electrode 530. Moreover, the wider extension of the first electrode 530 into the first portion 511 facilitates the setting of the via 130 on the side of the first portion 511 close to the substrate 100. For example, the orthographic projection of the via 130 on the substrate 100 is located within the orthographic projection of the first portion 511 on the substrate 100, further reducing the impact of the via 130 on the light emission of the light-emitting unit 310.

The orthographic projection of the isolation structure 201 on the substrate 100 is located within the orthographic projection of the pixel limiting portion 510 on the substrate 100, so as to improve the impact of the isolation structure 201 on the light emission of the light-emitting unit 310.

In some embodiments, the width of the pixel limiting portion 510 is 6 μm to 29 μm. For example, the width of the pixel limiting portion 510 is 6 μm, 8 μm, 15 μm, 19 μm, 29 μm, etc.

In these embodiments, the width of the pixel limiting portion 510 being greater than or equal to 6 μm can alleviate the problem that the pixel limiting portion 510 having a too small width leads to a small width of the isolation structure 201 located on the pixel limiting portion 510, thus a large resistance and an increased voltage drop of the isolation structure 201, and an increased power consumption of the display panel 10. It is also possible to alleviate the problem that the isolation structure 201 having a too small width leads to a small spacing between the two encapsulation portions 610 spaced apart in the first region 11 and thus it is difficult to perform filling and encapsulating with the second encapsulation layer made of organic material. The width of the pixel limiting portion 510 being less than or equal to 29 μm can alleviate the problem that the pixel limiting portion 510 having a too large width (i.e, the spacing between light-emitting units 310 being too large) results in a small area of the pixel opening 520 and a low opening ratio of the display panel.

Hereinafter, the overlapping of the encapsulation portions 610 corresponding to two light-emitting units 310 refers to the overlapping of the orthographic projections of the two encapsulation portions 610 on the substrate 100. The encapsulation portion 610 corresponding to the light-emitting unit 310 refers to the encapsulation portion 610 covering the light-emitting unit 310.

In some embodiments, the light-emitting unit 310 includes a third light-emitting unit 313, a second light-emitting unit 312, and a first light-emitting unit 311. At least one of the encapsulation portions 610 corresponding to the third light-emitting unit 313 and the second light-emitting unit 312 overlaps the encapsulation portion 610 corresponding to the first light-emitting unit 311.

In these embodiments, the encapsulation portions 610 corresponding to the third light-emitting unit 313 and the first light-emitting unit 311 overlap so as to extend an invasion path of water, oxygen and liquid medicine in the area between the third light-emitting unit 313 and the first light-emitting unit 311, which makes it difficult for the water, oxygen and liquid medicine to invade through the part of the encapsulation portion 610 located between the third light-emitting unit 313 and the first light-emitting unit 311, and avoids the damage to the light-emitting unit 310 caused by the invasion of the water, oxygen and liquid medicine, and the appearance of dark spots on the display panel 10; or the encapsulation portions 610 corresponding to the second light-emitting unit 312 and the first light-emitting unit 311 overlap so as to extend an invasion path of water, oxygen and liquid medicine in the area between the second light-emitting unit 312 and the first light-emitting unit 311, which makes it difficult for the water, oxygen and liquid medicine to invade through the part of the encapsulation portion 610 located between the second light-emitting unit 312 and the first light-emitting unit 311, and avoids the damage to the light-emitting unit 310 caused by the invasion of the water, oxygen and liquid medicine, and the appearance of dark spots on the display panel 10; or the encapsulation portions 610 corresponding to the third light-emitting unit 313 and the first light-emitting unit 311 overlap, and the encapsulation portions 610 corresponding to the second light-emitting unit 312 and the first light-emitting unit 311 overlap.

To provide sufficient space for arranging the via 130 and reduce the impact of the via 130 on the light emission of the light-emitting unit 310, the via 130 is set in the first region 11 and overlaps the isolation structure 201. For example, the via 130 corresponding to the third light-emitting unit 313 overlaps the orthographic projection of the isolation structure 201 in the first region 11 on the substrate 100; the via 130 corresponding to the second light-emitting unit 312 overlaps the orthographic projection of the isolation structure 201 in the first region 11 on the substrate 100; the via 130 corresponding to the first light-emitting unit 311 overlaps the orthographic projection of the isolation structure 201 in the first region 11 on the substrate 100.

As shown in FIGS. 12 and 13, when multiple third light-emitting units 313 and multiple second light-emitting units 312 are alternately arranged along the first direction X to form a first pixel group 350, and multiple first light-emitting units 311 are arranged along the first direction X to form a second pixel group 360, and the first pixel group 350 and the second pixel group 360 are alternately arranged along the second direction Y, the display panel 10 includes multiple arrayed pixel cells 370. The pixel cell 370 includes a first light-emitting unit 311, and a third light-emitting unit 313 and a second light-emitting unit 312 located on the same side of the first light-emitting unit 311 in the second direction Y. For two adjacent pixel cells 370, the encapsulation portion 610 corresponding to the third light-emitting unit 313 of one pixel cell 370 overlaps the encapsulation portion 610 corresponding to the second light-emitting unit 312 of the other pixel cell 370 to form the overlapping region 13.

In these embodiments, for two adjacent pixel cells 370 along the first direction X, the area between the third light-emitting unit 313 of one pixel cell 370 and the second light-emitting unit 312 of the other pixel cell 370 is located in the second region 12, where the width of the isolation structure 201 is smaller. The overlapping region 13 makes it possible to extend an invasion path of water, oxygen and liquid medicine in the area between the third light-emitting unit 313 in one pixel unit of the two adjacent pixel units 370 and the second light-emitting unit 312 in the other pixel unit of the two adjacent pixel units 370, which makes it difficult for the water, oxygen and liquid medicine to invade through the part of the encapsulation portion 610 located between the third light-emitting unit 313 and the second light-emitting unit 312, and avoids the damage to the light-emitting unit 310 caused by the invasion of the water, oxygen and liquid medicine, and the appearance of dark spots on the display panel 10.

In some embodiments, within the same pixel cell 370, the encapsulation portions 610 corresponding to the third light-emitting unit 313 and the second light-emitting unit 312 are spaced apart.

In these embodiments, within the same pixel cell 370, the area between the third light-emitting unit 313 and the second light-emitting unit 312 is located in the first region 11, where the width of the isolation structure 201 is set to be larger, and the spacing between the two adjacent encapsulation portions 610 is larger, which is beneficial for the subsequent filling of the second encapsulation layer made of organic material between the encapsulation portion 610 and the isolation structure 201, and improves the encapsulation effect.

The encapsulation portions 610 corresponding to adjacent first light-emitting units 311 are spaced apart. The area between the two adjacent first light-emitting units 311 is located in the first region 11, where the width of the isolation structure 201 is set to be larger, and the spacing between the two adjacent encapsulation portions 610 is larger, which is beneficial for the subsequent filling of the second encapsulation layer made of organic materials between the encapsulation portion 610 and the isolation structure 201, and improves the encapsulation effect.

In some embodiments, within the same pixel cell 370, the encapsulation portion 610 corresponding to the third light-emitting unit 313 overlaps the encapsulation portion 610 corresponding to the adjacent first light-emitting unit 311, and/or the encapsulation portion 610 corresponding to the second light-emitting unit 312 overlaps the encapsulation portion 610 corresponding to the adjacent first light-emitting unit 311.

In these embodiments, within the same pixel cell 370, the encapsulation portion 610 corresponding to the third light-emitting unit 313 overlaps the encapsulation portion 610 corresponding to the adjacent first light-emitting unit 311. That is, within the same pixel cell 370, the area between the third light-emitting unit 313 and the adjacent first light-emitting unit 311 is located in the second region 12, where the width of the isolation structure 201 is smaller. The overlapping makes it possible to extend an invasion path of water, oxygen and liquid medicine in the area between the third light-emitting unit 313 and the adjacent first light-emitting unit 311 within the same pixel unit 370, which makes it difficult for the water, oxygen and liquid medicine to invade through the part of the encapsulation portion 610 located between the third light-emitting unit 313 and the first light-emitting unit 311, and avoids the damage to the light-emitting unit 310 caused by the invasion of the water, oxygen and liquid medicine, and the appearance of dark spots on the display panel 10. Within the same pixel cell 370, the encapsulation portion 610 corresponding to the second light-emitting unit 312 overlaps the encapsulation portion 610 corresponding to the adjacent first light-emitting unit 311. That is, within the same pixel cell 370, the area between the second light-emitting unit 312 and the adjacent first light-emitting unit 311 is located in the second region 12, where the width of the isolation structure 201 is smaller. The overlapping makes it possible to extend an invasion path of water, oxygen and liquid medicine in the area between the second light-emitting unit 312 and the adjacent first light-emitting unit 311 within the same pixel unit 370, which makes it difficult for the water, oxygen and liquid medicine to invade through the part of the encapsulation portion 610 located between the second light-emitting unit 312 and the first light-emitting unit 311, and avoids the damage to the light-emitting unit 310 caused by the invasion of the water, oxygen and liquid medicine, and the appearance of dark spots on the display panel 10.

In some embodiments, within the pixel cell 370, the orthographic projection of the via 130 between the adjacent third light-emitting unit 313 and second light-emitting unit 312 on the substrate 100 is located outside of the orthographic projection of the encapsulation portion 610 on the substrate 100.

In these embodiments, the via 130 between the adjacent third light-emitting unit 313 and second light-emitting unit 312 within the pixel cell 370 is set in the area outside of the encapsulation portion 610, avoiding the problem that the via 130 is set below the encapsulation portion 610 (i.e., the orthographic projection of the via 130 on the substrate 100 overlaps the encapsulation portion 610), causing the encapsulation portion 610 to deform and be prone to fracture.

Due to the presence of the via 130, some of the material of the first electrode 530 falls into the via 130 to form a depression, which in turn causes depressions on the pixel limiting portion 510 and the isolation structure 201, and makes the encapsulation portion 610 corresponding to the via 130 be prone to collapse and deform.

Within the pixel cell 370, the via 130 between the adjacent third light-emitting unit 313 and second light-emitting unit 312 can have multiple options. For example, within the same pixel cell 370, the orthographic projection of the via 130 corresponding to the third light-emitting unit 313 on the substrate is located between the orthographic projections of the third light-emitting unit 313 and the second light-emitting unit 312 on the substrate 100. Or, within the same pixel cell 370, the orthographic projection of the via 130 corresponding to the second light-emitting unit 312 on the substrate is located between the orthographic projections of the third light-emitting unit 313 and the second light-emitting unit 312 on the substrate 100. Or, at least part of the orthographic projection of the via 130 corresponding to the first light-emitting unit 311 on the substrate is located between the orthographic projections of the third light-emitting unit 313 and the second light-emitting unit 312 on the substrate 100. All of these options can avoid the problem that the via 130 is set below the encapsulation portion 610, i.e., the orthographic projection of the via 130 on the substrate 100 overlaps the encapsulation portion 610, causing the encapsulation portion 610 to deform and be prone to fracture.

Within the same pixel cell 370, the orthographic projection of the via 130 corresponding to the first light-emitting unit 311 on the substrate 100 is located on the side of the orthographic projection of the first light-emitting unit 311 on the substrate 100 facing the orthographic projection of the third light-emitting unit 313 on the substrate 100.

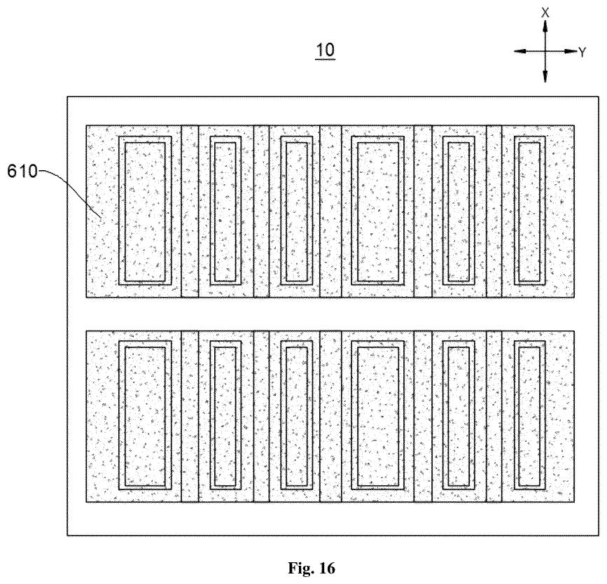

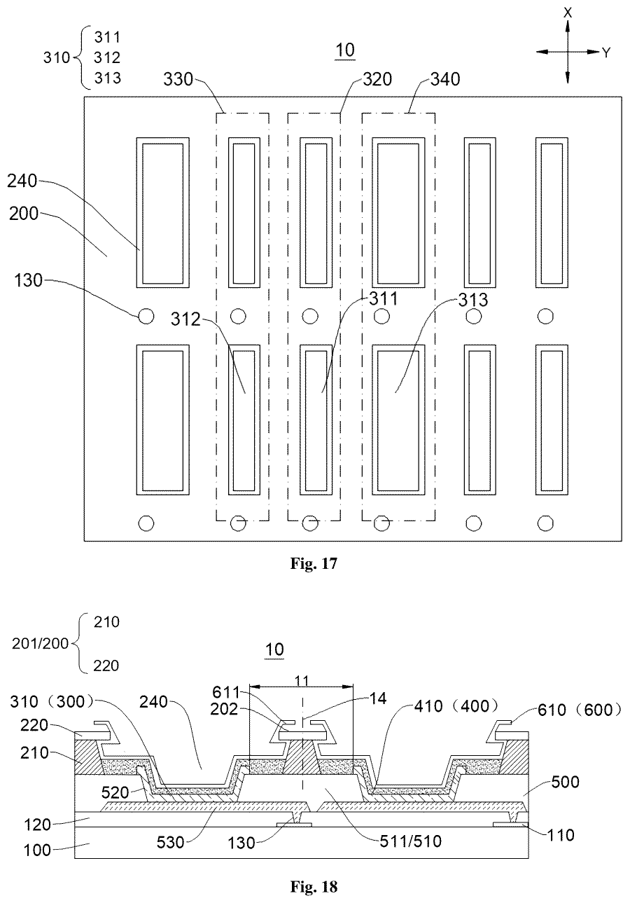

Please refer to FIGS. 16 and 17 together. FIG. 16 is a partial top view schematic diagram of a display panel in another embodiment; FIG. 17 is a partial top view schematic diagram of a display panel in another embodiment.

As shown in FIGS. 16 and 17, when multiple first light-emitting units 311 are arranged along the first direction X to form a first pixel column 320, multiple second light-emitting units 312 are arranged along the first direction X to form a second pixel column 330, multiple third light-emitting units 313 are arranged along the first direction X to form a third pixel column 340, and the first pixel column 320, the second pixel column 330, and the third pixel column 340 are alternately arranged along the second direction Y, the encapsulation portion 610 corresponding to the first light-emitting unit 311 overlaps the encapsulation portion 610 corresponding to the adjacent second light-emitting unit 312; the encapsulation portion 610 corresponding to the second light-emitting unit 312 overlaps the encapsulation portion 610 corresponding to the adjacent third light-emitting unit 313; and the encapsulation portion 610 corresponding to the first light-emitting unit 311 overlaps the encapsulation portion 610 corresponding to the adjacent third light-emitting unit 313.

In these embodiments, the encapsulation portion 610 corresponding to the first light-emitting unit 311 overlaps the encapsulation portion 610 corresponding to the adjacent second light-emitting unit 312. The area between the first light-emitting unit 311 and the adjacent second light-emitting unit 312 is located in the second region 12, where the width of the isolation structure 201 is smaller. The overlapping makes it possible to extend an invasion path of water, oxygen and liquid medicine in the area between the first light-emitting unit 311 and the adjacent second light-emitting unit 312, which makes it difficult for the water, oxygen and liquid medicine to invade through the part of the encapsulation portion 610 located between the first light-emitting unit 311 and the second light-emitting unit 312, and avoids the damage to the light-emitting unit 310 caused by the invasion of the water, oxygen and liquid medicine, and the appearance of dark spots on the display panel 10. The encapsulation portion 610 corresponding to the second light-emitting unit 312 overlaps the encapsulation portion 610 corresponding to the adjacent third light-emitting unit 313. The area between the second light-emitting unit 312 and the adjacent third light-emitting unit 313 is located in the second region 12, where the width of the isolation structure 201 is smaller. The overlapping makes it possible to extend an invasion path of water, oxygen and liquid medicine in the area between the second light-emitting unit 312 and the adjacent third light-emitting unit 313, which makes it difficult for the water, oxygen and liquid medicine to invade through the part of the encapsulation portion 610 located between the second light-emitting unit 312 and the third light-emitting unit 313, and avoids the damage to the light-emitting unit 310 caused by the invasion of the water, oxygen and liquid medicine, and the appearance of dark spots on the display panel 10. The encapsulation portion 610 corresponding to the first light-emitting unit 311 overlaps the encapsulation portion 610 corresponding to the adjacent third light-emitting unit 313. The area between the first light-emitting unit 311 and the adjacent third light-emitting unit 313 is located in the second region 12, where the width of the isolation structure 201 is smaller. The overlapping makes it possible to extend an invasion path of water, oxygen and liquid medicine in the area between the first light-emitting unit 311 and the adjacent third light-emitting unit 313, which makes it difficult for the water, oxygen and liquid medicine to invade through the part of the encapsulation portion 610 located between the first light-emitting unit 311 and the third light-emitting unit 313, and avoids the damage to the light-emitting unit 310 caused by the invasion of the water, oxygen and liquid medicine, and the appearance of dark spots on the display panel 10.

In some embodiments, the encapsulation portions 610 corresponding to adjacent first light-emitting units 311 are spaced apart. The encapsulation portions 610 corresponding to adjacent second light-emitting units 312 are spaced apart. The encapsulation portions 610 corresponding to adjacent third light-emitting units 313 are spaced apart.

In these embodiments, the encapsulation portions 610 corresponding to adjacent first light-emitting units 311 are spaced apart. The area between the two adjacent first light-emitting units 311 is located in the first region 11, where the width of the isolation structure 201 is set to be larger, and the spacing between the two adjacent encapsulation portions 610 is larger, which is beneficial for the subsequent filling of the second encapsulation layer made of organic material between the encapsulation portion 610 and the isolation structure 201, and improves the encapsulation effect. The encapsulation portions 610 corresponding to adjacent second light-emitting units 312 are spaced apart. The area between the two adjacent second light-emitting units 312 is located in the first region 11, where the width of the isolation structure 201 is set to be larger, and the spacing between the two adjacent encapsulation portions 610 is larger, which is beneficial for the subsequent filling of the second encapsulation layer made of organic material between the encapsulation portion 610 and the isolation structure 201, and improves the encapsulation effect. The encapsulation portions 610 corresponding to adjacent third light-emitting units 313 are spaced apart. The area between the two adjacent third light-emitting units 313 is located in the first region 11, where the width of the isolation structure 201 is set to be larger, and the spacing between the two adjacent encapsulation portions 610 is larger, which is beneficial for the subsequent filling of the second encapsulation layer made of organic material between the encapsulation portion 610 and the isolation structure 201, and improves the encapsulation effect.

The orthographic projection of the via 130 corresponding to the first light-emitting unit 311 on the substrate 100 is located between the orthographic projections of the two adjacent first light-emitting units 311 on the substrate 100. Due to the larger width of the isolation structure 201 between the two adjacent first light-emitting units 311, the spacing between the two adjacent first light-emitting units 311 is larger, facilitating the setting of the via 130 for the first light-emitting unit 311.

The orthographic projection of the via 130 corresponding to the second light-emitting unit 312 on the substrate 100 is located between the orthographic projections of the two adjacent second light-emitting units 312 on the substrate 100. Due to the larger width of the isolation structure 201 between the two adjacent second light-emitting units 312, the spacing between the two adjacent second light-emitting units 312 is larger, facilitating the setting of the via 130 for the second light-emitting unit 312.

The orthographic projection of the via 130 corresponding to the third light-emitting unit 313 on the substrate 100 is located between the orthographic projections of the two adjacent third light-emitting units 313 on the substrate 100. Due to the larger width of the isolation structure 201 between the two adjacent third light-emitting units 313, the spacing between the two adjacent third light-emitting units 313 is larger, facilitating the setting of the via 130 for the third light-emitting unit 313.

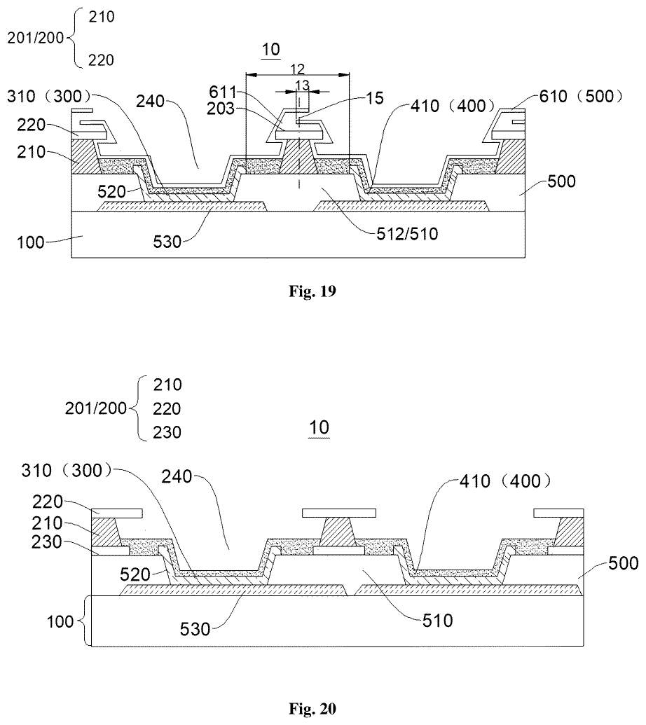

Please refer to FIGS. 18 and 19 together. FIG. 18 is a partial cross-sectional view of a display panel in another embodiment; FIG. 19 is a partial cross-sectional view of a display panel in another embodiment.

As shown in FIGS. 18 and 19, the encapsulation portion 610 includes an extension portion 611 located on the side of the isolation structure 201 facing away from the substrate 100 and spaced apart from the isolation structure 201. At least two adjacent extension portions 611 overlap to form an overlapping region 13, thereby extending the invasion path of water, oxygen and liquid medicine, and improving the encapsulation effect.

In some embodiments, the isolation structure 201 in the first region 11 has a first top surface 202 facing away from the substrate 100. The sum of the widths of the two extension portions 611 located on the side of the first top surface 202 facing away from the substrate 100 is less than or equal to the width of the first top surface 202.

The width of the extension portion 611 refers to a dimension of the extension portion 611 in the direction from an isolation opening 240 corresponding to the extension portion 611 to an adjacent isolation opening 240, and the width of the first top surface 202 refers to a dimension of the first top surface 202 in the direction from an isolation opening 240 to an adjacent isolation opening 240.

In these embodiments, the sum of the widths of the two extension portions 611 located on the side of the first top surface 202 facing away from the substrate 100 is less than or equal to the width of the first top surface 202, which makes the two extension portions 611 have a smaller width and can avoid the problem that two overlapping extension portions 611 having a too large width causes the extension portions 611 to be prone to fracture.

As shown in FIG. 18, the isolation structure 201 in the first region 11 has a first top surface 202 facing away from the substrate 100. The first top surface 202 is symmetrical about the first reference plane 14. The first reference plane 14 is perpendicular to the substrate 100 and extends through the first top surface 202. The encapsulation portions 610 corresponding to the light-emitting units 310 on two sides of the isolation structure 201 in the first region 11 are spaced apart on two sides of the first reference plane 14, meaning that in the first region 11, two adjacent encapsulation portions 610 are spaced apart on the first top surface 202.

As shown in FIG. 19, the isolation structure 201 in the second region 12 has a second top surface 203 facing away from the substrate 100. The second top surface 203 is symmetrical about the second reference plane 15. The second reference plane 15 is perpendicular to the substrate 100 and extends through the second top surface 203. At least one of the encapsulation portions 610 corresponding to the light-emitting units 310 on two sides of the isolation structure 201 in the second region 12 overlaps the second reference plane 15, meaning that in the second region 12, two adjacent encapsulation portions 610 overlap on the second top surface 203, and the overlapping region 13 overlaps the second reference plane 15, thereby avoiding the problem that one of the encapsulation portions 610 having a too large width on the isolation structure 201 is prone to fracture.

As shown in FIGS. 1 to 19, in some embodiments, the display panel 10 further includes: a second electrode layer 400, located on the side of the light-emitting layer 300 facing away from the substrate 100. The second electrode layer 400 includes a second electrode 410 located in the isolation opening 240. The second electrode 410 is electrically connected to the isolation structure 201.

In these embodiments, the isolation structure 201 separates the second electrode layer 400 to form second electrodes 410 that are spaced apart from each other. The spaced-apart second electrodes 410 are electrically connected through the isolation structure 201 to form a full-surface electrode, ensuring the normal light emission of the light-emitting unit 310. One of the second electrode 410 and the first electrode 530 serves as the anode of the light-emitting unit 310, and the other serves as the cathode of the light-emitting unit 310. In this embodiment, as an example for illustration, the second electrode 410 serves as the anode of the light-emitting unit 310, and the first electrode 530 serves as the cathode of the light-emitting unit 310.

In some embodiments, the orthographic projection of the light-emitting unit 310 on the substrate 100 is located within the orthographic projection of the second electrode 410 on the substrate 100.

In these embodiments, the orthographic projection of the light-emitting unit 310 on the substrate 100 is located within the orthographic projection of the second electrode 410 on the substrate 100. That is, the first electrode 530 covers the light-emitting unit 310 to serve as the electrode of the light-emitting unit 310, thereby ensuring the normal light emission of the light-emitting unit 310, and improving the display effect of the display panel 10.

The light-emitting unit 310 is spaced apart from the isolation structure 201. That is, the light-emitting units 310 are spaced apart from each other, thereby reducing the crosstalk of carriers between the light-emitting units 310, and alleviating the color bleeding problem of the light-emitting units 310.

The material of the first encapsulation layer 600 includes an inorganic material. The inorganic material has good compactness and good barrier properties to water vapor and oxygen.

The display panel 10 further includes: a second encapsulation layer, located on the side of the first encapsulation layer 600 facing away from the substrate 100; a third encapsulation layer, located on the side of the second encapsulation layer facing away from the substrate 100. The display panel 10 uses three layers of encapsulation, which has good encapsulation performance and reduces the possibility of water and oxygen invasion.

The material of the second encapsulation layer includes an organic material.

The material of the third encapsulation layer includes an inorganic material. The first encapsulation layer 600, the second encapsulation layer, and the third encapsulation layer are encapsulated with an inorganic material, an organic material, and an inorganic material, respectively, to form a TFE (Thin Film Encapsulation, TFE) film encapsulation structure, which further improves the encapsulation performance.

In some embodiments, the isolation structure 201 includes a first layer 210 and a second layer 220 located on the side of the first layer 210 facing away from the substrate 100. The orthographic projection of the surface of the first layer 210 facing away from the substrate 100 on the substrate 100 is located within the orthographic projection of the surface of the second layer 220 close to the substrate 100 on the substrate 100.

In these embodiments, the isolation structure 201 includes a first layer 210 and a second layer 220 located on the side of the first layer 210 away from the substrate 100. The first layer 210 and the second layer 220 are stacked to form the isolation structure 201. The orthographic projection of the first layer 210 close to the substrate 100 on the substrate 100 is located within the orthographic projection of the second layer 220 on the substrate 100. The area of the second layer 220 is larger than the area of the first layer 210, and the second layer 220 covers the surface of the first layer 210 close to the second layer 220. In this case, the first layer 210 is recessed relative to the second layer 220 in a direction away from the isolation opening 240.

In the present application, the sub-width of the isolation structure is defined as the larger one of the dimensions of the following two orthographic projections on the substrate: the orthographic projection of the surface of a side of the second layer away from the substrate, and the orthographic projection of the surface of a side of the second layer close to the substrate. Correspondingly, the isolation opening is defined as the opening formed by the edge of the larger one of the following two orthographic projections on the substrate: the orthographic projection of the surface of a side of the second layer away from the substrate, and the orthographic projection of the surface of a side of the second layer close to the substrate.

When preparing the light-emitting layer 300, if the light-emitting layer 300 has a significant height difference at the edge of the isolation structure 201 and the first layer is recessed relative to the second layer 220, it is difficult for the light-emitting layer 300 to maintain connection at the edge of the isolation structure 201, leading to fractures of the light-emitting layer 300. The fractures result in the formation of discrete light-emitting units 310, which in turn reduces carrier crosstalk within the light-emitting layer 300 and improves the display effect of the display panel 10. Furthermore, the fabrication of the light-emitting units 310 does not necessitate the use of precision masks, thereby reducing the development and utilization of precision masks and decreasing production costs.

The first layer 210 includes a conductive material, such as a non-metallic conductive material or a metallic conductive material.

In some embodiments, the second layer 220 includes a conductive material or an insulating material.

In these embodiments, the second layer 220 includes a conductive material, such as a non-metallic conductive material or a metallic conductive material. When the second layer 220 includes a non-metallic conductive material or an insulating material, it is difficult for the second layer 220 to be etched during the wet etching process of the first layer 210 with etchant, making it easier for the first layer 210 to be recessed relative to the second layer 220.

In some embodiments, both the first layer 210 and the second layer 220 include a metallic material, and the materials of the first layer 210 and the second layer 220 are different.

In these embodiments, when both the first layer 210 and the second layer 220 are metallic materials, a wet etching process with etchant can be used for the first layer 210. By setting the etchant, the etching rate of the second layer 220 can be made smaller than the etching rate of the first layer 210. Due to the larger etching rate of the first layer 210, even if the second layer 220 is etched to some extent, the etching of the first layer 210 is faster, and thus the first layer 210 is recessed relative to the second layer 220.

At least a portion of the second layer 220 has a width of 3 μm to 26 μm. For example, the width of the orthographic projection of the second layer 220 on the substrate 100 is 3 μm, 4 μm, 5 μm, 6 μm, etc. The width of the second layer 220 refers to a dimension of the second layer 220 in the direction from an isolation opening 240 to an adjacent isolation opening 240.

In these embodiments, the width of the second layer 220 being greater than or equal to 3 μm can alleviate the problem that the isolation structure 201 having a too small width leads to a large resistance and an increased voltage drop of the isolation structure 201, and an increased power consumption of the display panel 10. It is also possible to alleviate the problem that the isolation structure 201 having a too small width leads to a small spacing between the two encapsulation portions 610 spaced apart in the first region 11 and thus it is difficult to perform filling and encapsulating with the second encapsulation layer made of organic material. The width of the second layer 220 being less than or equal to 26 μm makes it possible to avoid the problem that due to a too large width of the isolation structure 201, in the second region 12, parts of two overlapping encapsulation portions 610 on the side of the isolation structure 201 facing away from the substrate 100 are too wide, leading to the parts of the encapsulation portions 610 on the side of the isolation structure 201 facing away from the substrate 100 being prone to fracture under force.

Please refer to FIG. 20, which is a partial cross-sectional view of a display panel in another embodiment.

As shown in FIG. 20, in some embodiments, the isolation structure 201 further includes a third layer 230 located on the side of the first layer 210 facing towards the substrate 100. The orthographic projection of the surface of the first layer 210 close to the substrate 100 on the substrate 100 is located within the orthographic projection of the surface of the third layer 230 away from the substrate 100 on the substrate 100.

In these embodiments, due to the faster etching rate of the first layer 210, the etching waste is more likely to enter other parts of the display panel 10, causing adverse effects. After setting the third layer 230, the first layer 210 can better adhere to the third layer 230, and the etching waste falls on the third layer 230, facilitating cleaning.

The light-emitting layer 300 includes an electron injection layer (EIL), an electron transport layer (ETL), a light-emitting material layer, a hole injection layer (HIL), and a hole transport layer (HTL).

As shown in FIGS. 1 to 20, the present application provides a display panel 10, which includes: a substrate 100; an isolation layer 200 located on a side of the substrate 100, the isolation layer 200 including an isolation structure 201 and a plurality of isolation openings 240 enclosed by the isolation structure 201; a pixel definition layer 500 located on a side of the substrate 100, the pixel definition layer 500 including a pixel limiting portion 510 and a plurality of pixel openings 520 enclosed by the pixel limiting portion 510, wherein at least a part of the pixel openings 520 correspond and communicate with the isolation openings 240 in a one-to-one correspondence; a light-emitting layer 300 located on a side of the substrate 100, the light-emitting layer 300 including a plurality of light-emitting units 310, at least a portion of the light-emitting unit 310 being located in the pixel opening 520, wherein there are a first region 11 and a second region 12 between adjacent light-emitting units 310, the width of the isolation structure 201 in the first region 11 is greater than the width of the isolation structure 201 in the second region 12, and the width of the pixel limiting portion 510 in the first region 11 is greater than the width of the pixel limiting portion 510 in the second region 12.

According to the display panel 10 of the present application, the display panel 10 includes a substrate 100, an isolation layer 200, a pixel definition layer 500, and a light-emitting layer 300. The isolation structure 201 of the isolation layer 200 encloses the isolation openings 240, and at least a portion of the light-emitting unit 310 of the light-emitting layer 300 is located in the isolation opening 240, which can alleviate the issue of light interference between adjacent light-emitting units 310. The pixel limiting portion 510 of the pixel definition layer 500 encloses the pixel openings 520 to set the light-emitting units 310, allowing the light-emitting units 310 to emit light normally. Moreover, the pixel limiting portion 510 defines the setting area of each light-emitting unit 310, reducing color bleeding between the light-emitting units 310. In the first region 11 where the pixel limiting portion 510 has a larger width, the width of the isolation structure 201 is set to be larger, realizing a differentiated design of the width of the isolation structure 201 in the first region 11 and the second region 12, reducing the resistance of the isolation structure 201 in the first region 11, reducing the voltage drop of the isolation structure 201, and thus reducing the overall power consumption of the display panel 10.

The display panel 10 provided by this embodiment and the display panel 10 in any of the above embodiments can be cross-referenced, for example, the setting methods of the isolation structure 201, the light-emitting units 310, the isolation openings 240, and the first encapsulation layer 600 can be referred to in the above text, and are not repeated here.

As shown in FIGS. 1 to 20, the present application provides a display panel 10, which includes: a substrate 100; an isolation structure 201 located on a side of the substrate 100, the isolation structure 201 enclosing a plurality of isolation openings 240; a light-emitting layer 300 located on a side of the substrate 100, the light-emitting layer 300 including a plurality of light-emitting units 310 located in the isolation openings 240; a first encapsulation layer 600 located on the side of the light-emitting layer 300 facing away from the substrate 100, the first encapsulation layer 600 including a plurality of encapsulation portions 610 each for encapsulating a corresponding light-emitting unit 310, orthographic projections of at least two adjacent encapsulation portions 610 on the substrate 100 overlap to form an overlapping region 13, wherein there are a first region 11 and a second region 12 between adjacent light-emitting units 310, the width of the isolation structure 201 in the first region 11 is greater than the width of the isolation structure 201 in the second region 12, the overlapping region 13 is located outside of the orthographic projection of the isolation structure 201 in the first region 11 on the substrate 100, and the overlapping region 13 is located within the orthographic projection of the isolation structure 201 in the second region 12 on the substrate 100.

According to the display panel 10 of the present application, the display panel 10 includes a substrate 100, an isolation layer 200, and a light-emitting layer 300. The isolation structure 201 of the isolation layer 200 encloses the isolation openings 240, and at least a portion of the light-emitting unit 310 of the light-emitting layer 300 is located in the isolation opening 240, which can alleviate the issue of light interference between adjacent light-emitting units 310. The width of the isolation structure 201 in the first region 11 is greater than the width of the isolation structure 201 in the second region 12, which increases the width of the isolation structure 201 in the first region 11, reduces the resistance of the isolation structure 201 in the first region 11, reduces the voltage drop of the isolation structure 201, and thus reduces the overall power consumption of the display panel 10. The overlapping region 13 is located outside of the orthographic projection of the isolation structure 201 in the first region 11 on the substrate 100. Within the first region 11, the orthographic projections of the adjacent encapsulation portions 610 on the substrate 100 are spaced apart. That is, the width of the isolation structure 201 corresponding to the spacing between the two encapsulation portions 610 is larger, which makes the spacing between the two adjacent encapsulation portions 610 larger is beneficial for subsequent filling a second encapsulation layer made of organic material between the encapsulation portion 610 and the isolation structure 201, thereby improving the encapsulation effect. The overlapping region 13 is located within the orthographic projection of the isolation structure 201 in the second region 12. In the second region 12, the orthographic projections of two adjacent encapsulation portions 610 on the substrate 100 overlap. That is, the width of the isolation structure 201 corresponding to the overlapping region 13 of the two encapsulation portions 610 is smaller, which makes the width of the two overlapping encapsulation portions 610 on a side of the isolation structure 201 facing away from the substrate 100 smaller, and makes it possible to avoid the problem of parts of the two overlapping encapsulation portions 610 on the side of the isolation structure 201 facing away from the substrate 100 being too wide, leading to the parts of the encapsulation portions 610 on the side of the isolation structure 201 facing away from the substrate 100 being prone to fracture under force.

The display panel 10 provided by this embodiment and the display panel 10 in any of the above embodiments can be cross-referenced, for example, the setting methods of the isolation structure 201, the light-emitting units 310, the isolation openings 240, and the first encapsulation layer 600 can be referred to in the above text, and are not repeated here.

The structural design in this embodiment can be applied to other display panels 10, and the specific choice can be made according to the actual situation. The present application does not impose any specific restrictions on it.

The second aspect of the present application further provides a display device, including any of the above embodiments of the display panel 10. Since the display device provided by the second aspect of the present application includes any of the above embodiments of the display panel 10, the display device provided by the second aspect of the present application has the beneficial effects of any of the above embodiments of the display panel 10, and will not be repeated here.

The display device provided by the present application includes but is not limited to mobile phones, personal digital assistants (Personal Digital Assistant, PDA), tablet computers, e-books, televisions, access control, smart fixed telephones, control panels, and other devices with display functions.

Those skilled in the art should understand that the above embodiments are exemplary rather than limiting. Different technical features appearing in different embodiments can be combined to achieve beneficial effects. Based on the study of the drawings, the specification, and the claims, those skilled in the art should be able to understand and implement other variations of the disclosed embodiments. In the claims, the term “including” does not exclude other devices or steps; when an item is not modified by a quantity word, it is intended to include one or more items, and can be interchangeable with “one or more items”; the terms “first”, “second” are used to indicate names rather than to indicate any specific order. Any reference marks in the claims should not be understood as limiting the scope of protection. The functions of multiple parts in the claims can be implemented by a single hardware or software module. The appearance of certain technical features in different dependent claims does not mean that these technical features cannot be combined to achieve beneficial effects.

What is claimed is:

1. A display panel comprising:
a substrate;
an isolation layer located on a side of the substrate, the isolation layer comprising an isolation structure and a plurality of isolation openings enclosed by the isolation structure;
a light-emitting layer located on a side of the substrate, the light-emitting layer comprising a plurality of light-emitting units, at least a portion of the light-emitting unit being located in the isolation opening, the plurality of the light-emitting units being arranged along a first direction and a second direction that intersect,
wherein the plurality of light-emitting units comprise a plurality of first light-emitting units, a plurality of second light-emitting units, a plurality of third light-emitting units and a plurality of fourth light-emitting units, the second light-emitting unit and the third light-emitting are adjacent to the first light-emitting unit in the second direction, the fourth light-emitting unit is adjacent to the first light-emitting unit in the first direction, a width of the isolation structure located between the first light-emitting unit and the second light-emitting unit is a first sub-width, a width of the isolation structure located between the first light-emitting unit and the third light-emitting unit is a second sub-width, a width of the isolation structure located between the first light-emitting unit and the fourth light-emitting unit is a third sub-width, a sum of the first sub-width and the second sub-width is less than the third sub-width, and the first direction and the second direction intersect.

2. The display panel according to claim 1, wherein the second light-emitting unit and the third light-emitting unit are respectively located on two sides of the first light-emitting unit, the plurality of light-emitting units further comprise a plurality of fifth light-emitting units, the fifth light-emitting unit is located in a same row as the first light-emitting unit, the second light-emitting unit, and the third light-emitting unit in the second direction, a width of the isolation structure between the fifth light-emitting unit and the third light-emitting unit is a fourth sub-width, wherein
at least one of a sum of the fourth sub-width and the first sub-width or a sum of the fourth sub-width and the second sub-width is less than the third sub-width;
or, the third sub-width is greater than at least one of the first sub-width or the second sub-width or the fourth sub-width;
or, the third sub-width is less than a sum of the first sub-width, the second sub-width, and the fourth sub-width;
or, luminous colors of the second light-emitting unit and the fifth light-emitting unit are the same.

3. The display panel according to claim 2, wherein a plurality of the first light-emitting units and a plurality of the fourth light-emitting units are arranged along the first direction to form a first pixel column, a plurality of the second light-emitting units are arranged along the first direction to form a second pixel column, a plurality of the third light-emitting units are arranged along the first direction to form a third pixel column, the first pixel column, the second pixel column, and the third pixel column are alternately arranged along the second direction;
wherein luminous colors of the first light-emitting unit, the second light-emitting unit, and the third light-emitting unit are different;
or, luminous colors of the first light-emitting unit and the fourth light-emitting unit are the same;
or, a width of the isolation structure located between two adjacent second light-emitting units is a fifth sub-width, and the third sub-width is equal to the fifth sub-width;
or, a width of the isolation structure located between two adjacent third light-emitting units is a sixth sub-width, and the third sub-width is equal to the sixth sub-width.

4. The display panel according to claim 2, wherein the plurality of isolation openings comprise a plurality of first isolation openings, a plurality of second isolation openings, and a plurality of third isolation openings, the first light-emitting unit is located in the first isolation opening, the second light-emitting unit is located in the second isolation opening, the third light-emitting unit is located in the third isolation opening, orthographic projections of adjacent first isolation opening, second isolation opening, and third isolation opening on the substrate are located in a same virtual quadrilateral; wherein
an orthographic projection of the isolation opening on the substrate has a first side and a second side that are set opposite to each other in the first direction, and the first side and the second side of each of the first isolation opening, the second isolation opening, and the third isolation opening coincide with a side of the virtual quadrilateral;
or, the orthographic projection of the isolation opening on the substrate further has a third side and a fourth side that are set opposite to each other in the second direction, and the third side of the second isolation opening and the fourth side of the third isolation opening coincide with a side of the virtual quadrilateral;
or, the orthographic projection of the isolation opening on the substrate further has four arc edges each located between either two of the first side, the second side, the third side, and the fourth side, to form a rounded rectangle;
or, the virtual quadrilateral is a rectangle.

5. The display panel according to claim 1, wherein the second light-emitting unit and the third light-emitting unit are located on a same side of the first light-emitting unit, a plurality of the second light-emitting units and a plurality of the third light-emitting units are alternately arranged along the first direction to form a first pixel group, a plurality of the first light-emitting units and a plurality of the fourth light-emitting units are arranged along the first direction to form a second pixel group, the first pixel group and the second pixel group are alternately arranged along the second direction;
a width of the isolation structure located between the second light-emitting unit and the third light-emitting unit along the first direction is a seventh sub-width, the seventh sub-width is equal to the third sub-width, and the sum of the first sub-width and the second sub-width is less than the seventh sub-width;
or, luminous colors of the first light-emitting unit, the second light-emitting unit, and the third light-emitting unit are different;
or, luminous colors of the first light-emitting unit and the fourth light-emitting unit are the same.

6. The display panel according to claim 1, wherein the display panel further comprises:
a pixel definition layer located on a side of the substrate, wherein the pixel definition layer comprises a pixel limiting portion and a plurality of pixel openings enclosed by the pixel limiting portion, at least a part of the pixel openings correspond to and communicate with the isolation openings in a one-to-one correspondence, a first region and a second region are provided between adjacent light-emitting units, a width of the isolation structure in the first region is greater than a width of the isolation structure in the second region, and a width of the pixel limiting portion in the first region is greater than a width of the pixel limiting portion in the second region.

7. The display panel according to claim 6, wherein a ratio of the width of the isolation structure to the width of the pixel limiting portion in the first region is greater than or equal to a ratio of the width of the isolation structure to the width of the pixel limiting portion in the second region;
or, the width of the isolation structure in the first region is greater than or equal to 1.5 times the width of the isolation structure in the second region;
or, a ratio of the width of the isolation structure to the width of the pixel limiting portion between two adjacent light-emitting units is greater than or equal to 0.5.

8. The display panel according to claim 1, wherein the display panel further comprises:
a first encapsulation layer located on a side of the light-emitting layer facing away from the substrate, wherein the first encapsulation layer comprises a plurality of encapsulation portions each of which is used for encapsulating a corresponding light-emitting unit, and orthographic projections of at least two adjacent encapsulation portions on the substrate overlap to form an overlapping region;
wherein a first region and a second region are provided between adjacent light-emitting units, a width of the isolation structure in the first region is greater than a width of the isolation structure in the second region, the overlapping region is located outside of an orthographic projection of the isolation structure in the first region on the substrate, and the overlapping region is located within an orthographic projection of the isolation structure in the second region on the substrate.

9. The display panel according to claim 8, wherein a ratio of a width of the overlapping region to the width of the isolation structure in the second region is less than or equal to 0.5.

10. A display panel comprising:
a substrate;
an isolation layer located on a side of the substrate, the isolation layer comprising an isolation structure and a plurality of isolation openings enclosed by the isolation structure;
a pixel definition layer located on a side of the substrate, wherein the pixel definition layer comprises a pixel limiting portion and a plurality of pixel openings enclosed by the pixel limiting portion, and at least a part of the pixel openings correspond to and communicate with the isolation openings in a one-to-one correspondence;
a light-emitting layer located on a side of the substrate, the light-emitting layer comprising a plurality of light-emitting units, at least a portion of the light-emitting unit being located in the pixel opening,
wherein a first region and a second region are provided between adjacent light-emitting units, a width of the isolation structure in the first region is greater than a width of the isolation structure in the second region, and a width of the pixel limiting portion in the first region is greater than a width of the pixel limiting portion in the second region.

11. The display panel according to claim 10, wherein a ratio of the width of the isolation structure to the width of the pixel limiting portion in the first region is greater than or equal to a ratio of the width of the isolation structure to the width of the pixel limiting portion in the second region.

12. The display panel according to claim 10, wherein a ratio of the width of the isolation structure to the width of the pixel limiting portion between two adjacent light-emitting units is greater than or equal to 0.5.

13. The display panel according to claim 10, wherein the plurality of light-emitting units comprise a plurality of first light-emitting units, a plurality of second light-emitting units, a plurality of third light-emitting units and a plurality of fourth light-emitting units, the second light-emitting unit and the third light-emitting are adjacent to the first light-emitting unit in a second direction and located on different sides of the first light-emitting unit, the fourth light-emitting unit is adjacent to the first light-emitting unit in a first direction, the isolation structure between the first light-emitting unit and the second light-emitting unit is the isolation structure located in the second region and has a width of a first sub-width, the isolation structure between the first light-emitting unit and the third light-emitting unit is the isolation structure located in the second region and has a width of a second sub-width, the isolation structure between the first light-emitting unit and the fourth light-emitting unit is the isolation structure located in the first region and has a width of a third sub-width, the sum of the first sub-width and the second sub-width is less than the third sub-width, and the first direction and the second direction intersect.

14. The display panel according to claim 13, wherein the plurality of light-emitting units further comprise a plurality of fifth light-emitting units, the fifth light-emitting unit is located in a same row as the first light-emitting unit, the second light-emitting unit, and the third light-emitting unit in the second direction, the isolation structure between the fifth light-emitting unit and the third light-emitting unit is the isolation structure located in the second region and has a width of a fourth sub-width;
at least one of a sum of the fourth sub-width and the first sub-width or a sum of the fourth sub-width and the second sub-width is less than the third sub-width;
or, the third sub-width is greater than at least one of the first sub-width or the second sub-width or the fourth sub-width;
or, the third sub-width is less than a sum of the first sub-width, the second sub-width, and the fourth sub-width;
or, luminous colors of the second light-emitting unit and the fifth light-emitting unit are the same.

15. The display panel according to claim 13, wherein a plurality of the first light-emitting units and a plurality of the fourth light-emitting units are arranged along the first direction to form a first pixel column, a plurality of the second light-emitting units are arranged along the first direction to form a second pixel column, a plurality of the third light-emitting units are arranged along the first direction to form a third pixel column, the first pixel column, the second pixel column, and the third pixel column are alternately arranged along the second direction;
luminous colors of the first light-emitting unit, the second light-emitting unit, and the third light-emitting unit are different;
or, luminous colors of the first light-emitting unit and the fourth light-emitting unit are the same;
or, the first light-emitting unit, the second light-emitting unit, and the third light-emitting unit adjacent to each other are arranged side by side in the second direction;
or, the isolation structure between two adjacent second light-emitting units is the isolation structure located in the first region and has a width of a fifth sub-width, the third sub-width is equal to the fifth sub-width;
or, the isolation structure between two adjacent third light-emitting units is the isolation structure located in the first region and has a width of a sixth sub-width, the third sub-width is equal to the sixth sub-width.

16. The display panel according to claim 10, wherein the plurality of light-emitting units comprise a plurality of first light-emitting units, a plurality of second light-emitting units, a plurality of third light-emitting units and a plurality of fourth light-emitting units, the second light-emitting unit and the third light-emitting are adjacent to the first light-emitting unit in the second direction and located on a same side of the first light-emitting unit, the fourth light-emitting unit is adjacent to the first light-emitting unit in the first direction, the isolation structure between the first light-emitting unit and the second light-emitting unit is the isolation structure located in the second region and has a width of a first sub-width, the isolation structure between the first light-emitting unit and the third light-emitting unit is the isolation structure located in the second region and has a width of a second sub-width, the isolation structure between the first light-emitting unit and the fourth light-emitting unit is the isolation structure located in the first region and has a width of a third sub-width;
a sum of the first sub-width and the second sub-width is less than the third sub-width;
or, a plurality of the second light-emitting units and a plurality of the third light-emitting units are alternately arranged along a first direction to form a first pixel group, a plurality of the first light-emitting units and a plurality of the fourth light-emitting units are arranged along the first direction to form a second pixel group, the first pixel group and the second pixel group are alternately arranged along a second direction;
or, luminous colors of the first light-emitting unit, the second light-emitting unit, and the third light-emitting unit are different;
or, luminous colors of the first light-emitting unit and the fourth light-emitting unit are the same.

17. The display panel according to claim 10, wherein the display panel further comprises:
a first encapsulation layer located on a side of the light-emitting layer facing away from the substrate, wherein the first encapsulation layer comprises a plurality of encapsulation portions each of which is used for encapsulating a corresponding light-emitting unit, and orthographic projections of at least two adjacent encapsulation portions on the substrate overlap to form an overlapping region;
wherein the first region and the second region are provided between adjacent light-emitting units, the width of the isolation structure in the first region is greater than the width of the isolation structure in the second region, the overlapping region is located outside of an orthographic projection of the isolation structure in the first region on the substrate, and the overlapping region is located within an orthographic projection of the isolation structure in the second region on the substrate.

18. A display panel comprising:
a substrate;
an isolation structure located on a side of the substrate, the isolation structure enclosing a plurality of isolation openings;
a light-emitting layer located on a side of the substrate, the light-emitting layer comprising a plurality of light-emitting units, the light-emitting unit being located in the isolation opening;
a first encapsulation layer located on a side of the light-emitting layer facing away from the substrate, wherein the first encapsulation layer comprises a plurality of encapsulation portions each of which is used for encapsulating a corresponding light-emitting unit, and orthographic projections of at least two adjacent encapsulation portions on the substrate overlap to form an overlapping region;
wherein a first region and a second region are provided between adjacent light-emitting units, a width of the isolation structure in the first region is greater than a width of the isolation structure in the second region, the overlapping region is located outside of an orthographic projection of the isolation structure in the first region on the substrate, and the overlapping region is located within an orthographic projection of the isolation structure in the second region on the substrate.

19. The display panel according to claim 18, wherein the width of the isolation structure in the first region is greater than or equal to 1.5 times the width of the isolation structure in the second region.

20. The display panel according to claim 18, wherein the display panel further comprises:
a pixel definition layer, located on a side of the substrate, wherein the pixel definition layer comprises a pixel limiting portion and a plurality of pixel openings enclosed by the pixel limiting portion, at least a part of the pixel openings correspond to and communicate with the isolation openings in a one-to-one correspondence;
a ratio of the width of the isolation structure to the width of the pixel limiting portion between two adjacent light-emitting units is greater than or equal to 0.5.

21. The display panel according to claim 20, wherein the display panel further comprises a drive circuit, a first insulating layer, and a first electrode stacked in a direction away from the substrate, the first electrode is located on a side of the light-emitting unit facing the substrate and is exposed by the isolation opening, the first insulating layer has a via, at least a portion of the first electrode is located within the via and electrically connected to the drive circuit, and an orthographic projection of the via on the substrate overlaps an orthographic projection of the isolation structure in the first region on the substrate.

22. The display panel according to claim 21, wherein the pixel definition layer comprises a first portion and a second portion, a width of the pixel limiting portion in the first region is greater than a width of the pixel limiting portion in the second region, the first portion is located in the first region, the second portion is located in the second region, a width of the first electrode on a side of the first portion is greater than or equal to a width of the first electrode on a side of the second portion.

23. The display panel according to claim 21, wherein the plurality of light-emitting units comprise a plurality of third light-emitting units, a plurality of second light-emitting units, and a plurality of first light-emitting units, the encapsulation portion corresponding to at least one of the third light-emitting unit and the second light-emitting unit overlaps the encapsulation portion corresponding to the first light-emitting unit;
or, the orthographic projection of the via corresponding to the third light-emitting unit on the substrate overlaps the orthographic projection of the isolation structure in the first region on the substrate;
or, the orthographic projection of the via corresponding to the second light-emitting unit on the substrate overlaps the orthographic projection of the isolation structure in the first region on the substrate;
or, the orthographic projection of the via corresponding to the first light-emitting unit on the substrate overlaps the orthographic projection of the isolation structure in the first region on the substrate.

24. The display panel according to claim 23, wherein a plurality of the third light-emitting units and a plurality of the second light-emitting units are alternately arranged along a first direction to form a first pixel group, a plurality of the first light-emitting units are arranged along the first direction to form a second pixel group, the first pixel group and the second pixel group are alternately arranged along a second direction;
luminous colors of the third light-emitting unit, the second light-emitting unit, and the first light-emitting unit are different;
or, an area of an orthographic projection of the first light-emitting unit on the substrate is greater than or equal to an area of an orthographic projection of the third light-emitting unit on the substrate, and/or the area of the orthographic projection of the first light-emitting unit on the substrate is greater than or equal to an area of an orthographic projection of the second light-emitting unit on the substrate.

25. The display panel according to claim 24, wherein the display panel comprises a plurality of pixel cells arranged in an array, the pixel cell comprises the first light-emitting unit, and the third light-emitting unit and the second light-emitting unit located on a same side of the first light-emitting unit in the second direction; for two adjacent pixel cells, the encapsulation portion corresponding to the third light-emitting unit of one pixel cell overlaps the encapsulation portion corresponding to the second light-emitting unit of the other pixel cell to form the overlapping region;
within a same pixel cell, the encapsulation portions corresponding to the third light-emitting unit and the second light-emitting unit are spaced apart;
or, the encapsulation portions corresponding to adjacent first light-emitting units are spaced apart;
or, within a same pixel cell, the encapsulation portion corresponding to the third light-emitting unit overlaps the encapsulation portion corresponding to the adjacent first light-emitting unit, and/or the encapsulation portion corresponding to the second light-emitting unit overlaps the encapsulation portion corresponding to the adjacent first light-emitting unit;
or, within the pixel cell, the orthographic projection of the via between the adjacent third light-emitting unit and second light-emitting unit on the substrate is located outside of the orthographic projection of the encapsulation portion on the substrate.

26. The display panel according to claim 25, wherein within a same pixel cell, the orthographic projection of the via corresponding to the third light-emitting unit on the substrate is located between the orthographic projections of the third light-emitting unit and the second light-emitting unit on the substrate;
or, within a same pixel cell, the orthographic projection of the via corresponding to the second light-emitting unit on the substrate is located between the orthographic projections of the third light-emitting unit and the second light-emitting unit on the substrate;
or, within a same pixel cell, the orthographic projection of the via corresponding to the first light-emitting unit on the substrate is located on a side of the orthographic projection of the first light-emitting unit facing the orthographic projection of the third light-emitting unit on the substrate;
or, at least part of the orthographic projection of the via corresponding to the third light-emitting unit on the substrate is located between the orthographic projections of the third light-emitting unit and the second light-emitting unit on the substrate.

27. The display panel according to claim 23, wherein a plurality of the first light-emitting units are arranged along the first direction to form a first pixel column, a plurality of the second light-emitting units are arranged along the first direction to form a second pixel column, a plurality of the third light-emitting units are arranged along the first direction to form a third pixel column, the first pixel column, the second pixel column, and the third pixel column are alternately arranged along the second direction;
luminous colors of the first light-emitting unit, the second light-emitting unit, and the third light-emitting unit are different.

28. The display panel according to claim 27, wherein the encapsulation portion corresponding to the first light-emitting unit overlaps the encapsulation portion corresponding to the adjacent second light-emitting unit, or the encapsulation portion corresponding to the second light-emitting unit overlaps the encapsulation portion corresponding to the adjacent third light-emitting unit, or the encapsulation portion corresponding to the first light-emitting unit overlaps the encapsulation portion corresponding to the adjacent third light-emitting unit;
or, the encapsulation portions corresponding to adjacent first light-emitting units are spaced apart, or the encapsulation portions corresponding to adjacent second light-emitting units are spaced apart, or the encapsulation portions corresponding to adjacent third light-emitting units are spaced apart;
or, the orthographic projection of the via corresponding to the first light-emitting unit on the substrate is located between the orthographic projections of two adjacent first light-emitting units on the substrate;
or, the orthographic projection of the via corresponding to the second light-emitting unit on the substrate is located between the orthographic projections of two adjacent second light-emitting units on the substrate;
or, the orthographic projection of the via corresponding to the third light-emitting unit on the substrate is located between the orthographic projections of two adjacent third light-emitting units on the substrate.

29. The display panel according to claim 21, wherein the encapsulation portion comprises an extension portion located on a side of the isolation structure facing away from the substrate and spaced apart from the isolation structure, at least two adjacent extension portions overlap to form the overlapping region;
the isolation structure in the first region has a first top surface facing away from the substrate, a sum of widths of two extension portions located on a side of the first top surface facing away from the substrate is less than or equal to a width of the first top surface; or, the isolation structure in the first region has a first top surface facing away from the substrate, the first top surface is symmetrical about a first reference plane, the first reference plane is perpendicular to the substrate and extends through the first top surface, the encapsulation portions corresponding to the light-emitting units on two sides of the isolation structure in the first region are spaced apart on two sides of the first reference plane;
or, the isolation structure in the second region has a second top surface facing away from the substrate, the second top surface is symmetrical about a second reference plane, the second reference plane is perpendicular to the substrate and extends through the second top surface, at least one of the encapsulation portions corresponding to the light-emitting units on two sides of the isolation structure in the second region overlaps the second reference plane.

30. The display panel according to claim 18, wherein the isolation structure comprises a first layer and a second layer located on a side of the first layer facing away from the substrate, an orthographic projection of the first layer on the substrate is located within an orthographic projection of the second layer on the substrate;
a width of the second layer in the first region is greater than a width of the second layer in the second region;
or, a ratio of a width of the overlapping region to the width of the isolation structure in the first region is less than or equal to 0.5.
